(19) United States
(12) Patent Application Publication
(10) Pub. No.: US 2025/0112597 A1
(43) Pub. Date: Apr. 3, 2025

(54) DYNAMIC BIASING CIRCUITRY FOR TRANSCONDUCTANCE AMPLIFIER STAGE

(71) Applicant: TEXAS INSTRUMENTS INCORPORATED, Dallas, TX (US)

(72) Inventors: Pallabi PRAMANIK, Bengaluru (IN); Mahadevan VENKITESWARAN, Bengaluru (IN)

(21) Appl. No.: 18/904,892

(22) Filed: Oct. 2, 2024

(30) Foreign Application Priority Data
Oct. 3, 2023 (IN) 202341066074

(51) Int. Cl. H03F 1/26; H03F 1/02; H03F 3/45; H03K 5/24

(52) U.S. Cl. CPC H03F 1/26; H03F 1/0222; H03F 1/0266; H03F 3/45475; H03K 5/2481

(57) ABSTRACT

An integrated circuit (IC) includes: first and second transistors having a respective first terminal, a respective second terminal, and a respective control terminal; and cascode circuitry having a first terminal, a second terminal, a third terminal, a fourth terminal, a fifth terminal, and a sixth terminal. The first terminal of the cascode circuitry is coupled to the control terminal of the first transistor. The second terminal of the cascode circuitry is coupled to the control terminal of the second transistor. The third terminal of the cascode circuitry is coupled to the second terminal of the first transistor. The fourth terminal of the cascode circuitry is coupled to the second terminal of the second transistor. The IC also includes dynamic biasing circuitry having a first terminal and a second terminal. The first terminal of the dynamic biasing circuitry is coupled to the first terminals of the first and second transistors.

### CROSS-REFERENCE TO RELATED APPLICATION

The present application is related to: India Provisional Application No. 202341066074, titled “QUICK RESPONSE DYNAMIC INPUT CIRCUIT FOR LOW POWER HIGH SPEED COMPARATOR”, Attorney Docket number T103892IN01, filed on Oct. 3, 2023, which is hereby incorporated by reference in its entirety.

### BACKGROUND

A transconductance amplifier stage converts an input voltage to an output current. Some transconductance amplifier stage designs have inconsistent output polarity in response to fast transients in the input voltage due to parasitic capacitances.

### SUMMARY

In an example, an integrated circuit (IC) includes: a first transistor having a first terminal, a second terminal, and a control terminal; a second transistor having a first terminal, a second terminal, and a control terminal; and cascode circuitry having a first terminal, a second terminal, a third terminal, a fourth terminal, a fifth terminal, and a sixth terminal. The first terminal of the cascode circuitry is coupled to the control terminal of the first transistor. The second terminal of the cascode circuitry is coupled to the control terminal of the second transistor. The third terminal of the cascode circuitry is coupled to the second terminal of the first transistor. The fourth terminal of the cascode circuitry is coupled to the second terminal of the second transistor. The IC also includes dynamic biasing circuitry having a first terminal and a second terminal. The first terminal of the dynamic biasing circuitry coupled to the first terminals of the first and second transistors.

In another example, a circuit includes a transconductance amplifier stage. The transconductance amplifier stage includes: a first transistor having a first terminal, a second terminal, and a control terminal; a second transistor having a first terminal, a second terminal, and a control terminal; and cascode circuitry having a first terminal, a second terminal, a third terminal, a fourth terminal, a fifth terminal, and a sixth terminal. The first terminal of the cascode circuitry is coupled to the second terminal of the first transistor. The second terminal of the cascode circuitry is coupled to the second terminal of the second transistor. The circuit also includes dynamic biasing circuitry coupled to the first terminals of first and second transistors. The dynamic biasing circuitry is configured to: detect a voltage transient at a target terminal of the transconductance amplifier stage; adjust a bias current responsive to the voltage transient; and provide the adjusted bias current to the first terminals of the first and second transistors.

In yet another example, a circuit includes a transconductance amplifier stage. The transconductance amplifier stage includes: a first transistor having a first terminal, a second terminal, and a control terminal; a second transistor having a first terminal, a second terminal, and a control terminal; a third transistor having a first terminal, a second terminal, and a control terminal; a fourth transistor having a first terminal, a second terminal, and a control terminal; a fifth transistor having a first terminal, a second terminal, and a control terminal, the second terminal of the fifth transistor coupled to the first terminals of the first and second transistors; and cascode circuitry having a first terminal, a second terminal, a third terminal, a fourth terminal, a fifth terminal, and a sixth terminal. The first terminal of the cascode circuitry is coupled to the control terminal of the first transistor and the second terminal of the third transistor. The second terminal of the cascode circuitry is coupled to the control terminal of the second transistor and the second terminal of the fourth transistor. The third terminal of the cascode circuitry is coupled to the second terminal of the first transistor. The fourth terminal of the cascode circuitry is coupled to the second terminal of the second transistor. The circuit also includes dynamic biasing circuitry having a first terminal and a second terminal. The second terminal of the dynamic biasing circuitry is coupled to the first terminal of the fifth transistor.

### BRIEF DESCRIPTION OF THE DRAWINGS

FIG. 1 is a diagram showing an example amplifier.

FIG. 2 is a diagram showing an example comparator.

FIG. 3 is a schematic diagram showing example integrated circuit (IC) circuitry with transconductance amplifier stage circuitry and dynamic biasing circuitry.

FIG. 4 is a schematic diagram showing other example IC circuitry with transconductance amplifier stage circuitry and dynamic biasing circuitry.

FIG. 5 is a schematic diagram showing example cascode circuitry.

FIG. 6 is a schematic diagram showing other example IC circuitry with transconductance amplifier stage circuitry and dynamic biasing circuitry.

FIG. 7 is a graph showing other voltages and currents of an example transconductance amplifier stage.

FIGS. 8 and 9 are graphs showing voltages related to a falling edge transition for an example comparator without dynamic biasing circuitry and/or without transient response circuitry.

FIGS. 10 and 11 include graphs showing voltages related to a falling edge transition for an example comparator with dynamic biasing circuitry and/or with transient response circuitry.

FIGS. 12 and 13 include graphs showing voltages related to a rising edge transition for an example comparator without dynamic biasing circuitry and/or without transient response circuitry.

FIGS. 14 and 15 include graphs showing voltages related to a rising edge transition for an example comparator with dynamic biasing circuitry and/or with transient response circuitry.

FIG. 16 is a flowchart showing an example control method for a transconductance amplifier stage.

### DETAILED DESCRIPTION

The same reference numbers or other reference designators are used in the drawings to designate the same or similar features. Such features may be the same or similar either by function and/or structure.

In the described examples, an integrated circuit (IC) includes: a transconductance amplifier stage and dynamic biasing circuitry coupled to the transconductance amplifier stage. The transconductance amplifier stage includes an input transistor pair and cascode circuitry. The input transistor pair has a first transistor and a second transistor. The first transistor has a first terminal, a second terminal, a control terminal, and a body terminal. The second transistor has a first terminal, a second terminal, a control terminal, and a body terminal. In some examples, the first and second transistors of the input transistor pair are in their own well separate from a substrate of the IC.

In some examples, the dynamic biasing circuitry operates to: detect an input voltage transient (e.g., a low-to-high transient or a high-to-low transient); and adjust a current provided to the input transistor pair responsive to the detected input voltage transient. In some examples, the dynamic biasing circuitry may also adjust a bias voltage provided to the body terminals of the first and second transistors to set the ground level of the first and second transistors. In some examples, the dynamic biasing circuitry includes clamp circuitry to limit the amount of current provided to the input transistor pair.

In some examples, a transconductance amplifier and/or cascode circuitry includes transient response circuitry. Examples of transient response circuitry include: clamping circuitry; discharge circuitry; and/or native (NAT) switches with near zero thresholds.

With the dynamic biasing circuitry and the transient response circuitry, the output response of a transconductance amplifier stage is improved compared to the output response of a transconductance amplifier stage without use of dynamic biasing circuitry and/or without use of transient response circuitry. In some examples, the transconductance amplifier stage supports a large input voltage range (e.g., 40V or more), low quiescent current (e.g., less than 50 to 60 uA overall of amp or comparator), and high speed transitions (e.g., faster up to 5v/10 ns). In some examples, the described transconductance amplifier stage is part of an amplifier or comparator, where the improved output response of the transconductance amplifier stage helps avoid glitches in the output of the amplifier or comparator.

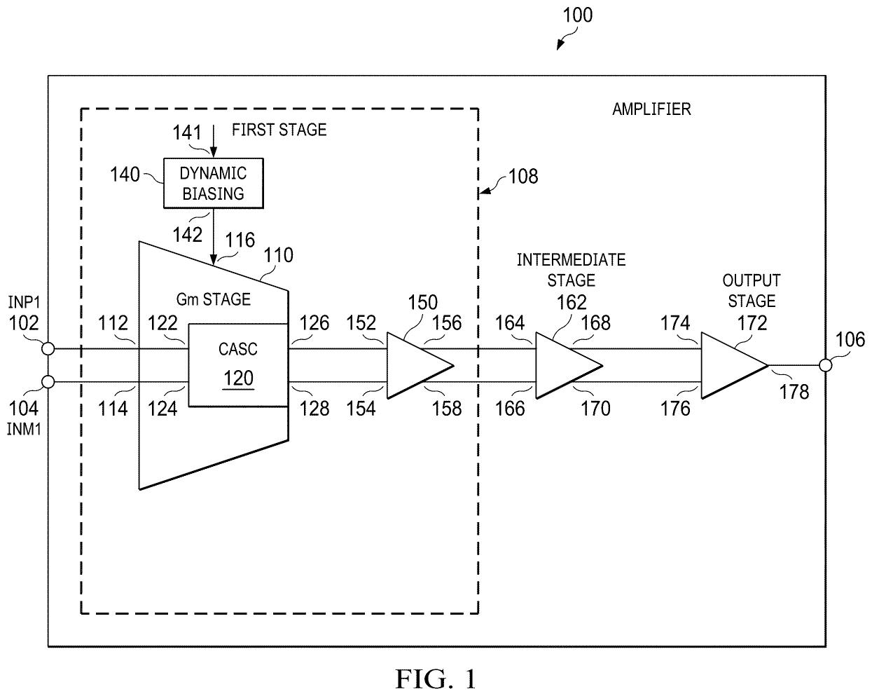

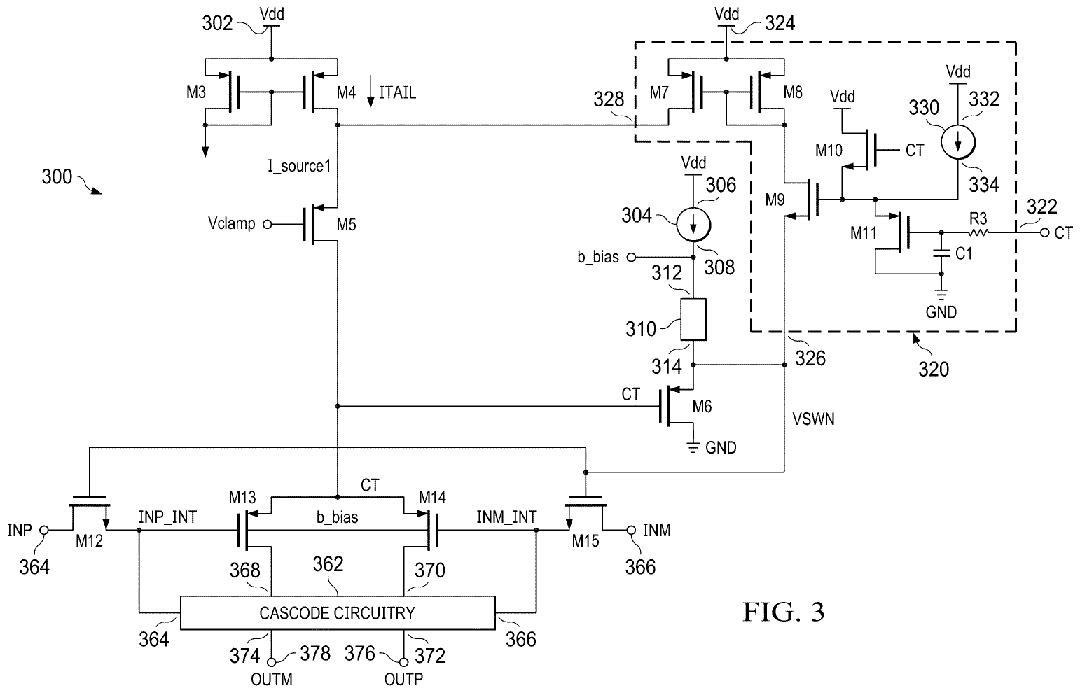

FIG. 1 is a diagram showing an example amplifier 100. The amplifier 100 has a first terminal 102, a second terminal 104, and a third terminal 106. The amplifier 100 includes a first stage 108, an intermediate stage 162, and an output stage 172. The first stage 108 includes a transconductance amplifier stage 110, dynamic biasing circuitry 140, and a gain stage 150. The transconductance amplifier stage 110 has a first terminal 112, a second terminal 114, a third terminal 126, a fourth terminal 128, and a fifth terminal 116. The transconductance amplifier stage 110 includes an input transistor pair (e.g., the transistors M13 and M14 in FIGS. 3 to 6) and cascode circuitry 120. The cascode circuitry 120 has a first terminal 122 and a second terminal 124 and shares the third and fourth terminals 126 and 128 with the transconductance amplifier stage 110. The dynamic biasing circuitry 140 has a first terminal 141 and a second terminal 142. The gain stage 150 has a first terminal 152, a second terminal 154, a third terminal 156, and a fourth terminal 158. The intermediate stage 162 has a first terminal 164, a second terminal 166, a third terminal 168, and a fourth terminal 170. The output stage 172 has a first terminal 174, a second terminal 176, and a third terminal 178.

The first terminal 102 of the amplifier 100 is coupled to the first terminal 112 of the transconductance amplifier stage 110 and the first terminal 122 of the cascode circuitry 120. The second terminal 104 of the amplifier 100 is coupled to the second terminal 114 of the transconductance amplifier stage 110 and the second terminal 124 of the cascode circuitry 120. The third terminal 126 shared by the cascode circuitry 120 and the transconductance amplifier stage 110 is coupled to the first terminal 152 of the gain stage 150. The fourth terminal 128 shared by the cascode circuitry 120 and the transconductance amplifier stage 110 is coupled to the second terminal 154 of the gain stage 150. The fifth terminal 116 of the transconductance amplifier stage 110 is coupled to the second terminal 142 of the dynamic biasing circuitry 140. The third terminal 156 of the gain stage 150 is coupled to the first terminal 164 of the intermediate stage 162. The fourth terminal 158 of the gain stage 150 is coupled to the second terminal 166 of the intermediate stage 162. The third terminal 168 of the intermediate stage 162 is coupled to the first terminal 174 of the output stage 172. The fourth terminal 170 of the intermediate stage 162 is coupled to the second terminal 176 of the intermediate stage 162. The third terminal 178 of the intermediate stage 162 is coupled to the third terminal 106 of the amplifier 100.

In some examples, the amplifier 100 includes an input transistor pair (e.g., the transistors M13 and M14 in FIGS. 3, 4, and 6) and operates to: receive a positive input voltage (INP1) at the first terminal 102; receive a negative input voltage (INM1) at the second terminal 104; generate outputs current using the input transistor responsive to the INP1 and INM1; apply gain using the gain stage 150; bias the output stage 172 using the intermediate stage 162; and drive an output load current using the output stage 172, resulting in the amplified result at the third terminal 106.

In some examples, the transconductance amplifier stage 110 of the first stage 108 operates to: receive INP1 at the first terminal 112; receive INM1 at the second terminal 114; provide a first current at the third terminal 126 responsive to INP1 and/or INM1, the operations of the dynamic biasing circuitry 140, and the operations of the cascode circuitry 120; and provide a second current at the fourth terminal 128 responsive to INP1 and/or INM1, the operations of the dynamic biasing circuitry 140, and the operations of the cascode circuitry 120.

In some examples, the dynamic biasing circuitry 140 operates to: sense a voltage of the transconductance amplifier stage 110 at the first terminal 141; and provide an adjusted current at the second terminal 142 responsive to the sensed voltage. In some examples, the voltage sensed by the dynamic biasing circuitry 140 is at a common terminal (CT) or first terminals of the input transistor pair of the transconductance amplifier stage 110 (e.g., the CT or first terminals of the transistors M13 and M14 in FIGS. 3 to 6). The cascode circuitry 120 operates to: sense INP1 (e.g., INP_INT is the sensed INP in FIGS. 3 to 6) at the first terminal 122; sense INM1 (e.g., INM_INT is the sensed INM in FIGS. 3 to 6) at the second terminal 124; receive the current from the input pair (e.g., the transistors M13 and M14) corresponding to the INP/INM polarity; provide the first current at the third terminal 126 responsive to the sensed INP1 and/or the sensed INM1, the adjusted current, and/or the biasing; and provide the second current at the fourth terminal 128 responsive to INP1 and/or INM1, the adjusted current, and/or the biasing. In some examples, the cascode circuitry 120 includes transient response circuitry to clamp, discharge, or otherwise regulate voltages to ensure the output currents from the cascode circuitry 120 accurately track the polarity of INP1 and INM1, even if INP1 and/or INM1 transients are fast (e.g., up to 5v/10 ns).

In some examples, the gain stage 150 operates to: receive the first current at the first terminal 152; receive the second current at the second terminal 154; apply a gain; and provide first voltages at the third and fourth terminals 156 and 158 responsive to first current, the second current, and the applied gain. Is some examples, the first voltages are a balanced differential result.

In some examples, the intermediate stage 162 operates to: receive the first voltages output from the gain stage 150 at the first and second terminals 164 and 166; and provide second voltages at the third and fourth terminals 168 and 170 responsive to first voltages and the operations of the intermediate stage 162. In some examples, the intermediate stage 162 applies a gain to the first voltages to provide the second voltages. In some examples, the second voltages are an unbalanced differential result.

In some examples, the output stage 172 operates to: receive the second voltages at the first and second terminals 174 and 176; and provide the amplified result responsive to the second voltages and operations of the output stage 172. In some examples, the output stage 172 determines an output voltage and current range of the amplifier 100. With the dynamic biasing circuitry 140 and/or transient response circuitry for the cascode circuitry 120, the output currents from the cascode circuitry 120 accurately track the polarity of INP1 and INM1, even if INP1 and/or INM1 transients are fast (e.g., up to 5v/10 ns). With accurate polarity for the output currents from the transconductance amplifier stage 210, glitches in the output of the amplifier 100 are avoided.

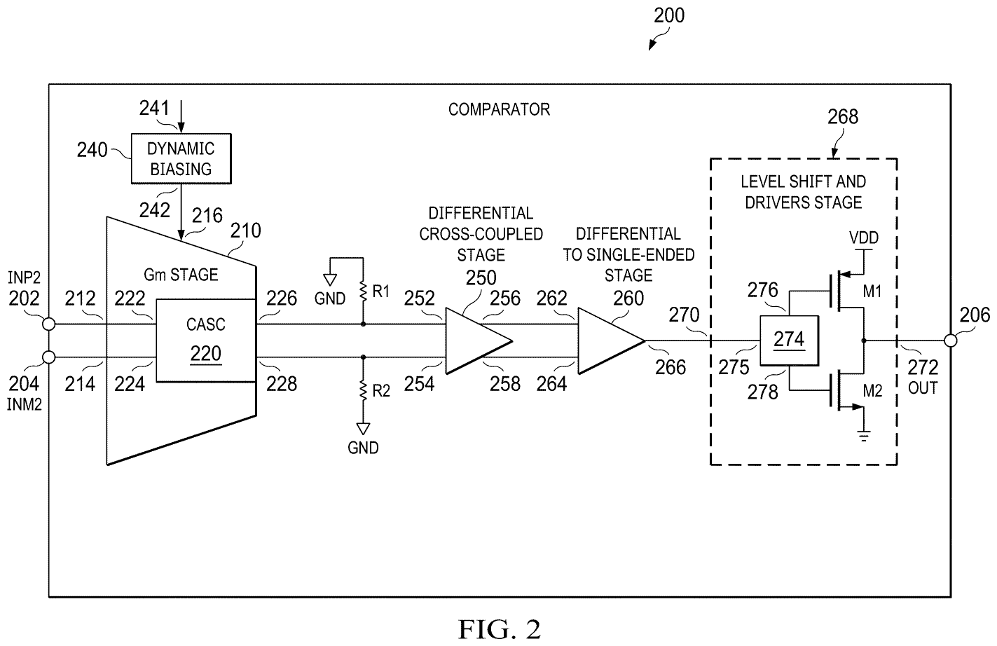

FIG. 2 is a diagram showing another example comparator 200. The comparator 200 has a first terminal 202, a second terminal 204, and a third terminal 206. The comparator 200 includes dynamic biasing circuitry 240, a transconductance amplifier stage 210, resistors R1 and R2, a differential cross-coupled stage 250, a differential to single-ended stage 260, and a level shift and drivers stage 268. The dynamic biasing circuitry 240 has a first terminal 241 and a second terminal 242. The transconductance amplifier stage 210 has a first terminal 212, a second terminal 214, a third terminal 226, and a fourth terminal 228, and a fifth terminal 216. The transconductance amplifier stage 210 includes an input transistor pair (e.g., transistor M13 and M14 in FIGS. 3 to 6) and cascode circuitry 220. The cascode circuitry 220 has a first terminal 222, a second terminal 224, and shares the third terminal 226 and the fourth terminal 228 with the transconductance amplifier stage 210. The dynamic biasing circuitry 240 has a first terminal 241 and a second terminal 242. The resistor R1 has a first terminal and a second terminal. The resistor R2 has a first terminal and a second terminal. The differential cross-coupled stage 250 has a first terminal 252, a second terminal 254, a third terminal 256, and a fourth terminal 258. The differential to single-ended stage 260 has a first terminal 262, a second terminal 264, and a third terminal 266. The level shift and drivers stage 268 has a first terminal 270 and a second terminal 272. The level shift and drivers stage 268 includes level shift circuitry 274, a transistor M1, and a transistor M2. The level shift circuitry 274 has a first terminal 275, a second terminal 276, and a third terminal 278. The transistor M1 has a first terminal, a second terminal, and a control terminal. The transistor M2 has a first terminal, a second terminal, and a control terminal. In the example of FIG. 2, the transistor M1 is an n-channel metal oxide semiconductor (NMOS) transistor, while the transistor M2 is a p-channel metal oxide semiconductor (PMOS) transistor.

The first terminal 202 of the comparator 200 is coupled to the first terminal 212 of the transconductance amplifier stage 210 and the first terminal 222 of the cascode circuitry 220. The second terminal 204 of the comparator 200 is coupled to the second terminal 214 of the transconductance amplifier stage 210 and the second terminal 224 of the cascode circuitry 220. The third terminal 226 shared by the cascode circuitry 220 and the transconductance amplifier stage 210 is coupled to the first terminal of the resistor R1, and the first terminal 252 of the differential cross-coupled stage 250. The second terminal of the resistor R1 is coupled to ground or a ground terminal. The fourth terminal 228 shared by the cascode circuitry 220 and the transconductance amplifier stage 210 is coupled to the first terminal of the resistor R2 and the second terminal 254 of the differential cross-coupled stage 250. The fifth terminal 216 of the transconductance amplifier stage 210 is coupled to the second terminal 242 of the dynamic biasing circuitry 240. The second terminal of the resistor R2 is coupled to ground or a ground terminal. The third terminal 256 of the differential cross-coupled stage 250 is coupled to the first terminal 262 of the differential to single-ended stage 260. The fourth terminal 258 of the differential cross-coupled stage 250 is coupled to the second terminal 264 of the differential to single-ended stage 260. The third terminal 266 of the differential to single-ended stage 260 is coupled to the first terminal 270 of the level shift and drivers stage 268 and the first terminal of the level shift circuitry 274. The second terminal of the level shift circuitry 274 is coupled to the control terminal of the transistor M1. The third terminal of the level shift circuitry 274 is coupled to the control terminal of the transistor M2. The first terminal of the transistor M1 is coupled to a power supply or related terminal. The second terminal of the transistor M1 is coupled to the first terminal of the transistor M2 and the second terminal 272 of the level shift and driver stage 268. The second terminal of the transistor M2 is coupled to ground or a ground terminal.

In some examples, the comparator 200 operates to: receive a positive input voltage (INP2) at the first terminal 202; receive a negative input voltage (INM2) at the second terminal 204; compare the differential voltage between INP2 and INM2 with a threshold to obtain a comparison result; and provide comparator output at the third terminal 206 responsive to the comparison result. In some examples, the comparator output at the third terminal 206 may be: a logical “1” or related voltage value when the differential voltage between INP2 and INM2 is positive; and a logical “0” or related voltage value when the differential voltage between INP2 and INM2 is negative.

In some examples, the transconductance amplifier stage 210 operates to: receive INP2 at the first terminal 212; receive INM2 at the second terminal 214; provide a first current at the third terminal 226 responsive to INP2, INM2, the operations of the dynamic biasing circuitry 240; and the operations of the cascode circuitry 220; and provide a second current at the fourth terminal 228 responsive to INP2, INM2, the operations of the dynamic biasing circuitry 240, and the operations of the cascode circuitry 220.

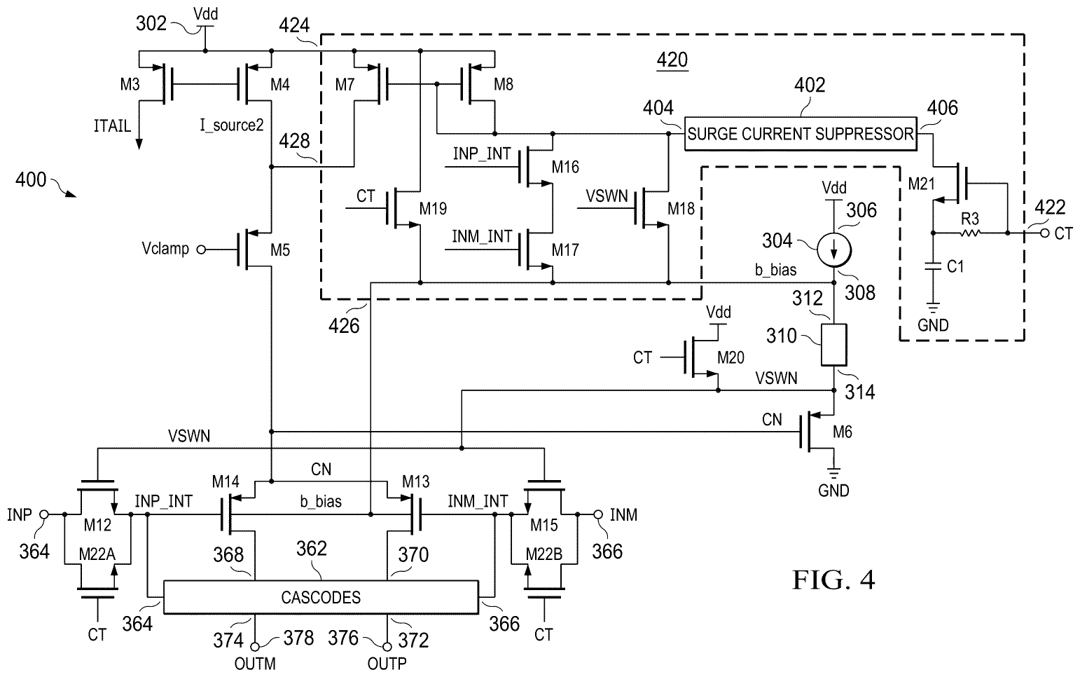

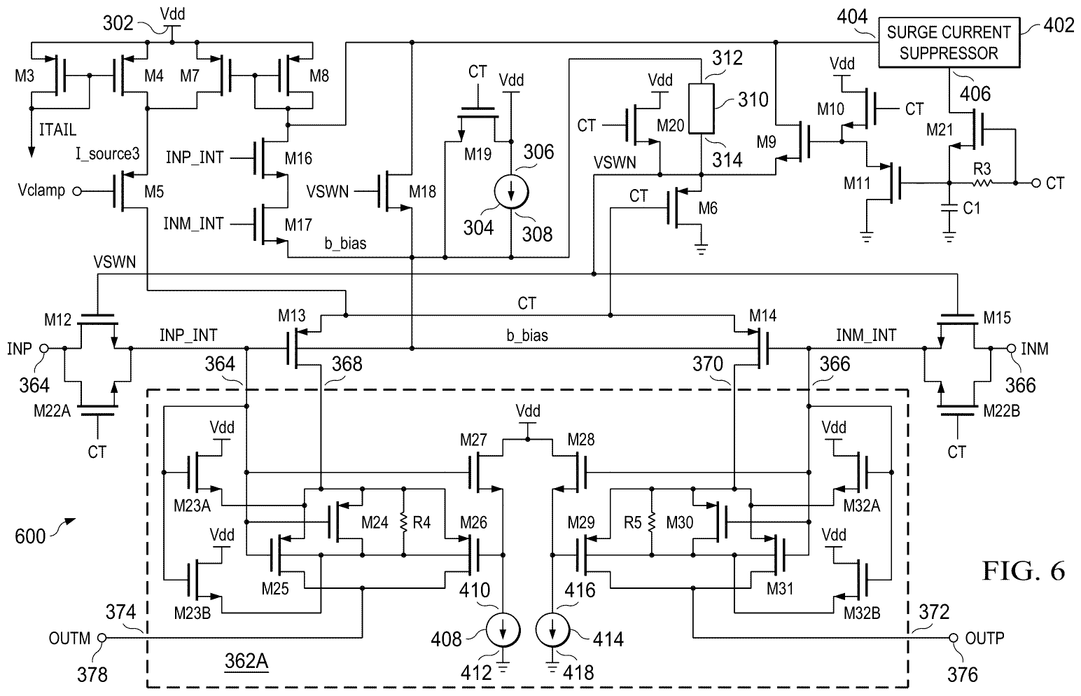

In some examples, the dynamic biasing circuitry 240 operates to: sense a voltage of the transconductance amplifier stage 210 at the first terminal 241; and provide an adjusted current at the second terminal 242 responsive to the sensed voltage. In some examples, the voltage sensed by the dynamic biasing circuitry 240 is at the CT or the first terminals of the input transistor pair of the transconductance amplifier stage 210 (e.g., the CT or first terminals of the transistors M13 and M14 in FIGS. 3 to 6). The cascode circuitry 220 operates to: sense INP1 (e.g., INP_INT is the sensed INP in FIGS. 3 to 6) at the first terminal 222; sense INM1 (e.g., INM_INT is the sensed INM in FIGS. 3 to 6) at the second terminal 224; receive the adjusted current (e.g., I_source1 in FIG. 3, I_source2 in FIG. 4, or I_source3 in FIG. 6) from the dynamic biasing circuitry 240, and/or biasing (e.g., b_bias in FIGS. 3 to 6); provide the first current at the third terminal 226 responsive to the sensed INP1 and/or the sensed INM1, the adjusted current, and/or the biasing; and provide the second current at the fourth terminal 228 responsive to INP1 and/or INM1, the adjusted current, and/or the biasing. In some examples, the cascode circuitry 220 includes transient response circuitry to clamp, discharge, or otherwise regulate voltages to ensure the output currents from the cascode circuitry 120 accurately track the polarity of INP1 and INM1, even if INP1 and/or INM1 transients are fast (e.g., up to 5v/10 ns).

In some examples, the resistor R1 sets a first voltage level at the first terminal 252 of the differential cross-coupled stage 250 responsive to the first current at the third terminal 226 of the transconductance amplifier stage 210. The resistor R2 sets a second voltage level at the second terminal 254 of the differential cross-coupled stage 250 responsive to the second current at the fourth terminal 228 of the transconductance amplifier stage 210.

In some examples, the differential cross-couple stage 250 operates to: receive the first voltage level at the first terminal 252; receive the second voltage level at the second terminal 254; provide a balanced differential result at the third and fourth terminals 256 and 258 responsive to first voltage level, the second voltage level, and operations of the differential cross-coupled stage 250. In some examples, the differential cross-coupled stage 250 applies a gain to the difference between the first and second voltage levels to produce the balanced differential result.

In some examples, the differential to single-ended stage 260 operates to: receive the balanced differential result at the first and second terminals 262 and 264; and provide an amplified result at the third terminals 266 responsive to balanced differential result and operations of the differential to single-ended stage 260. In some examples, the differential to single-ended stage 260 applies a gain to the balanced differential result to provide the amplified result.

In some examples, the level shift and drivers stage 268 operates to: receive the amplified result at the first terminal 270; generate level-shifted control signals based on the amplified result using the level shift circuitry 274; and provide the level shifted control signals to the transistors M1 and M2. The level-shifted control signals to the transistors M1 and M2 result in the comparator output at the second terminal 272 of the level shift and drivers stage 268. In some examples, the comparator output at the third terminal 206 may be: a logical “1” or related voltage value when the differential voltage between INP2 and INM2 is positive; and a logical “0” or relative voltage value when the differential voltage between INP2 and INM2 is negative.

With the dynamic biasing circuitry 240 and/or transient response circuitry for the cascode circuitry 220, the output currents from the cascode circuitry 220 accurately track the polarity of INP1 and INM1, even if INP1 and/or INM1 transients are fast (e.g., up to 5v/10 ns). With accurate polarity for the output currents from the transconductance amplifier stage 210, glitches in the output of the comparator 200 are avoided.

FIG. 3 is a schematic diagram showing example IC circuitry 300 with transconductance amplifier stage circuitry (e.g., the input transistor pair M13 and M14, and the cascode circuitry 362) and dynamic biasing circuitry 320. The IC circuitry 300 is an example of part of the amplifier 100 in FIG. 1, or part of the comparator 200 in FIG. 2. In the example of FIG. 3, the IC circuitry 300 has a first terminal 364, a second terminal 366, a third terminal 368, and a fourth terminal 370. The first terminal 364 is an example of the first terminal 112 in FIG. 1, or the first terminal 212 in FIG. 2. The second terminal 366 is an example of the second terminal 114 in FIG. 1, or the second terminal 214 in FIG. 2. The third terminal 376 is an example of the third terminal 126 in FIG. 1, or the third terminal 226 in FIG. 2. The fourth terminal 378 is an example of the fourth terminal 128 in FIG. 1, or the fourth terminal 228 in FIG. 2.

In the example of FIG. 3, the IC circuitry 300 includes transconductance amplifier stage circuitry including: an input transistor pair with transistors M13 and M14; and the cascode circuitry 362. The cascode circuitry 362 has a first terminal 364, a second terminal 366, a third terminal 368, a fourth terminal 370, a fifth terminal 372, and a sixth terminal 374. The dynamic biasing circuitry 320 has a first terminal 322, a second terminal 324, a third terminal 326, and a fourth terminal 328. The first terminal 322 of the dynamic biasing circuitry 320 is an example of the first terminal 141 in FIG. 1, or the first terminal 241 in FIG. 2. The fourth terminal 328 of the dynamic biasing circuitry 320 is an example of the second terminal 142 in FIG. 1, or the second terminal 242 in FIG. 2. The transistor M13 has a first terminal, a second terminal, a control terminal, and a body terminal. The transistor M14 has a first terminal, a second terminal, a control terminal, and a body terminal. The body terminals of the transistors M13 and M14 are used to set or adjust a ground voltage level for the transistors.

In the example of FIG. 3, the IC circuitry 300 includes transistors M3 to M15, a first current source 304, a second current source 330, voltage drop circuitry 310 (e.g., a resistor, a diode, or a transistor), a capacitor C1, and a resistor R3. Each of the transistors M3 to M15 has a respective first terminal, a respective second terminal, and a respective control terminal. In the example of FIG. 3, the transistors M3 to M8, M11, M13, and M14 are PMOS transistors, while the transistors M9, M10, M12, and M15 are NMOS transistors. The first current source 304 has a first terminal 306 and second terminal 308. The second current source 330 has a first terminal 332 and a second terminal 334. The voltage drop circuitry 310 has a first terminal 312 and a second terminal 314. The capacitor C1 has a first terminal and a second terminal. The resistor R3 has a first terminal and a second terminal. In the example of FIG. 3, the transistors M7 to M11, the second current source 330, the capacitor C1, and the resistor R3 are components of the dynamic biasing circuitry 320. The first current source 304, the voltage drop circuitry 310, and the transistor M6 are used to set a bias voltage (b_bias) applied to the body terminals of the transistors M13 and M14. The transistors M3 and M4 mirror a current (ITAIL) to the input transistor pair. The transistor M5 compares a common mode voltage with Vclamp and controls the on/off state of the first current source 304 accordingly. For example, if the common mode voltage is equal to or greater then Vclamp, the transistor M5 turns offs first current source 304. If the common mode voltage is less than Vclamp, the transistor M5 turns on the first current source 304.

In the example of FIG. 3, the first terminals of the transistors M3 and M4 are coupled to a power supply (Vdd) terminal 302. The second terminal of the transistor M3 is coupled to a current source (not shown) and the control terminals of the transistors M3 and M4, resulting in a tail current (Itail). The second terminal of the transistor M4 is coupled to the first terminal of the transistor M5 and the fourth terminal 328 of the dynamic biasing circuitry 320. The control terminal of the transistor M5 receives a clamp control signal (Vclamp) from a clamp controller (now shown). In some examples, Vclamp is controlled responsive to a common mode voltage level. The second terminal of the transistor M5 is coupled to the first terminals of the transistors M13 and M14. The voltage at the first terminals of the transistors M13 and M14 is referred to as a common node voltage (CT voltage or “V_{CT}”) herein. The second terminal of the transistor M13 is coupled to the third terminal 368 of the cascode circuitry 362. The control terminal of the transistor M13 is coupled to the second terminal of the transistor M12 and the first terminal 364 of the cascode circuitry 362. The first terminal of the transistor M12 is coupled to the first terminal 364 of the IC circuitry 300. The second terminal of the transistor M14 is coupled to the fourth terminal 370 of the cascode circuitry 362. The control terminal of the transistor M14 is coupled to the second terminal of the transistor M15 and the second terminal 366 of the cascode circuitry 362. The first terminal of the transistor M15 is coupled to the second terminal 366 of the IC circuitry 300. The fifth terminal 372 of the cascode circuitry 362 is coupled to the third terminal 376 of the IC circuitry 300. The sixth terminal 374 of the cascode circuitry 362 is coupled to the fourth terminal 378 of the IC circuitry 300.

The first terminal 322 of the dynamic biasing circuitry 320 is coupled to the first terminals of the transistors M13 and M14. The second terminal 324 of the dynamic biasing circuitry 320 is coupled to the power supply terminal 302. The third terminal 326 of the dynamic biasing circuitry 320 is coupled to the control terminals of the transistors M12 and M15. The second terminal 324 of the dynamic biasing circuitry 320 is coupled to the first terminals of the transistors M7 and M8. The second terminal of the transistor M7 is coupled to the fourth terminal 328 of the dynamic biasing circuitry 320. The second terminal of the transistor M8 is coupled to the control terminals of the transistors M7 and M8 and the first terminal of the transistor M9. The second terminal of the transistor M9 is coupled to the third terminal 326 of the dynamic biasing circuitry 320. The control terminal of the transistor M9 is coupled to the second terminal of the transistor M10, the second terminal 334 of the second current source 330, and the first terminal of the transistor M11. The first terminal of the transistor M10 and the first terminal 332 of the second current source 330 are coupled to the power supply terminal 302. The control terminal of the transistor M10 is coupled to the first terminal 322 of the dynamic biasing circuitry 320. The second terminal 334 of the transistor M11 is coupled to the second terminal of the capacitor C1 and ground or a ground terminal. The control terminal of the transistor M11 is coupled to the second terminal of the resistor R3. The first terminal of the resistor R3 is coupled to the first terminal 322 of the dynamic biasing circuitry 320.

As shown, the first terminal 306 of the first current source 304 is coupled to the power supply terminal 302. The second terminal 308 of first current source 304 is coupled to the first terminal 312 of the voltage drop circuitry 310. In the example of FIG. 3, the voltage at the first terminal 312 of the voltage drop circuitry 310 is b_bias (sometimes referred to as a backgate bias voltage herein), which is provided to respective body terminals of the transistors M13 and M14 as a ground reference. The second terminal 314 of the voltage drop circuitry 310 is coupled to the first terminal of the transistor M6 and the third terminal 326 of the dynamic biasing circuitry 320. The second terminal of the transistor M6 is coupled to ground or a ground terminal.

In the example of FIG. 3, the transistors M3 and M4 mirror ITAIL to the first terminal of the transistor M5. ITAIL is combined with a bias current from the dynamic biasing circuitry 320 (i.e., the current at the fourth terminal 328 of the dynamic biasing circuitry 320), resulting in a combined current (I_source1). The transistor M5 clamps I_source1 responsive to Vclamp. The clamped I_source1 is provided to the first terminals of the transistors M13 and M14.

The dynamic biasing circuitry 320 operates to: sense the CT voltage at the first terminal 322; control the transistor M11 based on the sensed CT voltage, the resistor R3, and the capacitor C1; control the transistor M10 based on the sensed CT voltage; control the transistor M9 based on the difference between CT voltage and VSWN; and mirror current through the transistor M9 to the fourth terminal 328 using the transistors M8 and M7.

In some examples, the first current source 304, the voltage drop circuitry 310, and the transistor M6 adjust the switch voltage VSWN, which is provided to the control terminals of the transistors M12 and M15. In some examples, the switch voltage VSWN is set based on the current provided by the first current source 304, the voltage drop due to the voltage drop circuitry 310, control of the transistors M6 and M9. In the example of FIG. 3, the switch voltage VSWN is used to: control M12 to perform sensing of INP, resulting in INP_INT; and control M15 to perform sensing of INM, result in INM_INT. The sensed INP level (INP_INT) controls the transistor M13 and is input to the first terminal 364 of the cascode circuitry 362. The sensed INM level (INM_INT) controls the transistor M14 and is input to the second terminal 366 of the cascode circuitry 362.

With the dynamic biasing circuitry 320, the IC circuitry 300 is able to add current to ITAIL based on transients in the positive input INP (e.g., INP1 in FIG. 1, or INP2 in FIG. 2) at the first terminal 364 and/or transients in the negative input INM (e.g., INM1 in FIG. 1, or INM2 in FIG. 2) at the second terminal 366, resulting in I_source1. I_source1 is clamped using the transistor M5. The clamped I_source1 provides current to the cascode circuitry 362 via the transistors M13 and M14, which are controlled using the switch voltage VSWN. With b_bias applied to the body terminal of the transistor M13, the transistor M13 is controlled responsive to the difference between INP_INT and b_bias. With b_bias applied to the body terminal of the transistor M14, the transistor M14 is controlled responsive to the difference between INM_INT and b_bias.

In the example of FIG. 3, the cascode circuitry 362 operates to: receive INP_INT at the first terminal 364; receive INM_INT at the second terminal 366; receive a first bias current at the third terminal 368 responsive to the clamped I_source1 and the operations of the transistor M13; receive a second bias current at the fourth terminal 370 responsive to the clamped I_source1 and the operations of the transistor M14; provide a first output current at the fifth terminal 372 responsive to INP_INT and the current through the transistor M13; and provide a second output current at the sixth terminal 374 responsive to INM_INT and the current through the transistor M14. With the dynamic biasing circuitry 320, the IC circuitry 300 adds current to I_source1 in response to detection of a falling edge transient in INP and/or INM. Adding current to I_source1 responsive to a falling edge transient in INP and/or INM ensures the polarity of the output currents from the cascode circuitry 362 tracks the polarity of INP and INM correctly, even if INP1 and/or INM1 rising edge transients are fast (e.g., up to 5v/10 ns).

FIG. 4 is a schematic diagram showing example IC circuitry 400 with transconductance amplifier stage circuitry (e.g., the input transistor pair M13 and M14, and the cascode circuitry 362) and dynamic biasing circuitry 420. The IC circuitry 400 is an example of part of the amplifier 100 in FIG. 1, or part of the comparator 200 in FIG. 2. In the example of FIG. 4, the IC circuitry 400 has the first terminal 364, the second terminal 366, the third terminal 368, and the fourth terminal 370 described in FIG. 3. The first terminal 364 is an example of the first terminal 112 in FIG. 1, or the first terminal 212 in FIG. 2. The second terminal 366 is an example of the second terminal 114 in FIG. 1, or the second terminal 214 in FIG. 2. The third terminal 376 is an example of the third terminal 126 in FIG. 1, or the third terminal 226 in FIG. 2. The fourth terminal 378 is an example of the fourth terminal 128 in FIG. 1, or the fourth terminal 228 in FIG. 2.

In the example of FIG. 4, the IC circuitry 400 includes transconductance amplifier stage circuitry including: the input transistor pair with transistors M13 and M14; and the cascode circuitry 362. The dynamic biasing circuitry 420 has a first terminal 422, a second terminal 424, a third terminal 426, and a fourth terminal 428. The first terminal 422 of the dynamic biasing circuitry 320 is an example of the first terminal 141 in FIG. 1, or the first terminal 241 in FIG. 2. The fourth terminal 428 of the dynamic biasing circuitry 420 is an example of the second terminal 142 in FIG. 1, or the second terminal 242 in FIG. 2. The cascode circuitry 362, the transistor M13, and the transistor M14 have the respective terminals described in FIG. 3.

In the example of FIG. 4, the IC circuitry 400 includes the transistors M3 to M8, and M12 to M15. The IC circuitry 400 also includes transistors M16 to M21, M22A, and M22B, the first current source 304, the voltage drop circuitry 310 (e.g., a resistor, a diode, or a transistor), the capacitor C1, the resistor R3, and surge current suppressor 402 (e.g., a current clamp). Each of the transistors M3 to M8, M12 to M21 has a respective first terminal, a respective second terminal, and a respective control terminal. In the example of FIG. 4, the transistors M3 to M8, M13, and M14 are PMOS transistors, while the transistors M12 to M21, M22A, and M22B are NMOS transistors. The first current source 304, the voltage drop circuitry 310, capacitor C1, and the resistor R3 have the terminals described in FIG. 3. The surge current suppressor 402 has a first terminal 404 and a second terminal 406. In the example of FIG. 4, the transistors M7, M8, M16 to M21, the capacitor C1, the resistor R3, and the surge current suppressor 402 are components of the dynamic biasing circuitry 420. The first current source 304, the voltage drop circuitry 310, and the transistor M6 are used to set b_bias, which is applied to the body terminals of the transistors M13 and M14.

In the example of FIG. 4, the first terminals of the transistors M3 and M4 are coupled to the power supply terminal 302. The second terminal of the transistor M3 is coupled to an ITAIL current source (not shown) and the control terminals of the transistors M3 and M4. The second terminal of the transistor M4 is coupled to the first terminal of the transistor M5 and the fourth terminal 428 of the dynamic biasing circuitry 420. The control terminal of the transistor M5 receives the clamp control signal Vclamp from a clamp controller (not shown). In some examples, Vclamp is controlled responsive to a common mode voltage level. The second terminal of the transistor M5 is coupled to the first terminals of the transistors M13 and M14. The voltage at the first terminals of the transistors M13 and M14 is the CT voltage. The second terminal of the transistor M13 is coupled to the third terminal 368 of the cascode circuitry 362. The control terminal of the transistor M13 is coupled to the second terminal of the transistor M12 and the first terminal 364 of the cascode circuitry 362. The first terminal of the transistor M12 is coupled to the first terminal 364 of the IC circuitry 400. The second terminal of the transistor M14 is coupled to the fourth terminal 370 of the cascode circuitry 362. The control terminal of the transistor M14 is coupled to the second terminal of the transistor M15 and the second terminal 366 of the cascode circuitry 362. The first terminal of the transistor M15 is coupled to the second terminal 366 of the IC circuitry 400. The fifth terminal 372 of the cascode circuitry 362 is coupled to the third terminal 376 of the IC circuitry 400. The sixth terminal 374 of the cascode circuitry 362 is coupled to the fourth terminal 378 of the IC circuitry 400.

The first terminal 422 of the dynamic biasing circuitry 420 is coupled to the first terminals of the transistors M13 and M14. The second terminal 424 of the dynamic biasing circuitry 420 is coupled to the power supply terminal 302. The third terminal 426 of the dynamic biasing circuitry 420 is coupled to the body terminals of the transistors M13 and M14. The second terminal 424 of the dynamic biasing circuitry 320 is coupled to the first terminals of the transistors M7 and M8. The second terminal of the transistor M7 is coupled to the fourth terminal 428 of the dynamic biasing circuitry 420. The second terminal of the transistor M8 is coupled to the first terminals of the transistors M16, M19, and M18, and the first terminal 404 of the surge current suppressor 402. The second terminal of the transistor M16 is coupled to the first terminal of the transistor M17. The control terminal of the transistor M19 is coupled to the CT. The control terminal of the transistor M16 is coupled to the second terminal of the transistors M12 and M22A and receives INP_INT. The control terminal of the transistor M17 is coupled to the second terminal of the transistors M15 and M22B and receives INM_INT. The second terminals of the transistors M17, M18, M19 are coupled to the third terminal 426 of the dynamic biasing circuitry 420, the second terminal 308 of the first current source 304, and the first terminal 312 of the voltage drop circuitry 310. The first terminal 306 of the first current source 304 is coupled to the power supply terminal 302. The second terminal 406 of the surge current suppressor 402 is coupled to the first terminal of the transistor M21. The second terminal of the transistor M21 is coupled to the first terminal of the capacitor C1 and the second terminal of the resistor R3. The second terminal of the capacitor C1 is coupled to ground or a ground terminal. The first terminal of the resistor R3 is coupled to the first terminal 422 of the dynamic biasing circuitry 420 and the control terminal of the transistor M21.

The second terminal 314 of the voltage drop circuitry 310 is coupled to the first terminal of the transistor M6, the second terminal of the transistor M20, and the control terminals of the transistors M12 and M15. The second terminal of the transistor M6 is coupled to ground or a ground terminal. The first terminal of the transistor M20 is coupled to the power supply terminal 302. The control terminal of the transistor M20 is coupled to the CT (the first terminals of the transistor M13 and M14).

In the example of FIG. 4, the transistors M3 and M4 mirror ITAIL to the first terminal of the transistor M5. ITAIL is combined with a bias current from the dynamic biasing circuitry 420 (i.e., the current at the fourth terminal 428 of the dynamic biasing circuitry 420), resulting in combined current I_source2. The transistor M5 clamps I_source2 responsive to Vclamp. The clamped I_source2 is provided to the first terminals of the transistors M13 and M14.

The dynamic biasing circuitry 420 operates to: sense the CT voltage at the first terminal 422; control the transistor M21 based on the sensed CT voltage, the resistor R3, and the capacitor C1; regulate the current through the transistor M21 using the surge current suppressor 402; adjust b_bias using the transistors M16 to M18 and related control signals (the CT voltage, INP_INT, INM_INT, and VSWN); mirror current to the fourth terminal 428 using the transistors M7 and M8.

In some examples, the first current source 304, the voltage drop circuitry 310, and the transistor M6 adjust the switch voltage VSWN, which is provided to the control terminals of the transistors M12, M15, and M18. In some examples, the switch voltage VSWN is set based on the current provided by the first current source 304, the voltage drop due to the voltage drop circuitry 310, and control of the transistors M6 and M20. In the example of FIG. 4, the switch voltage VSWN is used to: control M12 to perform sensing of INP, resulting in INP_INT; and control M15 to perform sensing of INM, result in INM_INT. The sensed INP level (INP_INT) controls the transistor M13 and is input to the first terminal 364 of the cascode circuitry 362. The sensed INM level (INM_INT) controls the transistor M14 and is input to the second terminal 366 of the cascode circuitry 362.

With the dynamic biasing circuitry 420, the IC circuitry 400 is able to add current to ITAIL based on transients in the positive input INP (e.g., INP1 in FIG. 1, or INP2 in FIG. 2) at the first terminal 364 and/or transients in the negative input INM (e.g., INM1 in FIG. 1, or INM2 in FIG. 2) at the second terminal 366, resulting in I_source2. I_source2 is clamped using the transistor M5. The clamped I_source2 is provided to the cascode circuitry 362 via the transistors M13 and M14, which are controlled using the switch voltage VSWN. With b_bias applied to the body terminal of the transistor M13, the transistor M13 is controlled responsive to the difference between INP_INT and b_bias. With b_bias applied to the body terminal of the transistor M14, the transistor M14 is controlled responsive to the difference between INM_INT and b_bias.

In the example of FIG. 4, the cascode circuitry 362 operates to: receive INP_INT at the first terminal 364; receive INM_INT at the second terminal 366; receive a first bias current at the third terminal 368 responsive to the clamped I_source2 and the operations of the transistor M13; receive a second bias current at the fourth terminal 370 responsive to the clamped I_source2 and the operations of the transistor M14; provide a first output current at the fifth terminal 372 responsive to INP_INT and the current through the transistor M13; and provide a second output current at the sixth terminal 374 responsive to INM_INT and the current through the transistor M14. With the dynamic biasing circuitry 420, the IC circuitry 400 adds current to I_source2 in response to detection of a falling edge transient in INP and/or INM. Also, the transistors M22A and M22B enable quicker response by the cascode circuitry 362 to falling edge transients in INM and INP to ensure the polarity of the output currents from the cascode circuitry 362 track the polarity of INP and INM correctly, even if INP1 and/or INM1 falling edge transients are fast (e.g., up to 5v/10 ns).

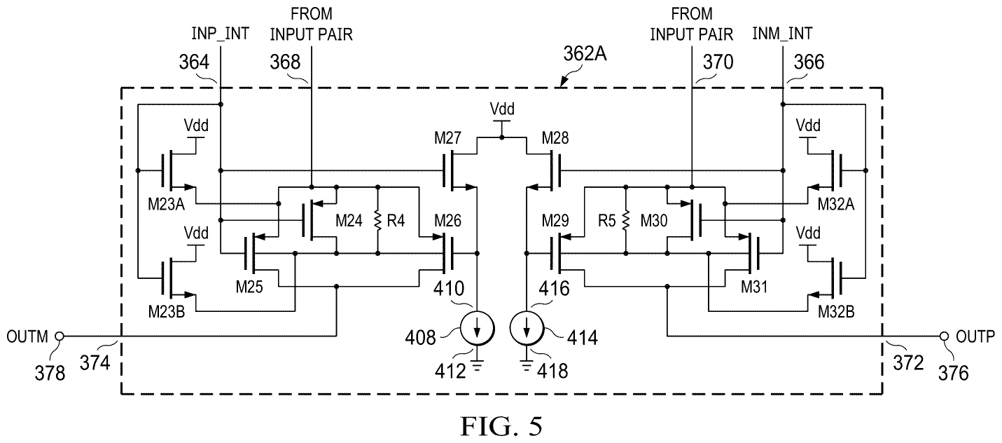

FIG. 5 is a schematic diagram showing example cascode circuitry 362A. The cascode circuitry 362A is an example of the cascode circuitry 120 in FIG. 1, the cascode circuitry 220 in FIG. 2, and the cascode circuitry 362 in FIGS. 3 and 4. In the example of FIG. 5, the cascode circuitry 362A has the first terminal 364, the second terminal 366, the third terminal 368, the fourth terminal 370, the fifth terminal 372, and the sixth terminal 374 described in FIGS. 3 and 4. The cascode circuitry 362 includes: transistors M23A, M23B, M24 to M31, M32A, and M32B; resistors R4 and R5; a first current source 408; and a second current source 414. Each of the transistors M23A, M23B, M24, M27, M28, M30, M32A, and M32B have a respective first terminal, a respective second terminal, and a respective control terminal. Each of the transistors M25, M26, M29, and M31 have a respective first terminal, a respective second terminal, a respective control terminal, and a respective body terminal. In the example of FIG. 5, the transistors M24, M25, M26, M29, M30, and M31 are PMOS transistors, while the transistors M23A, M23B, M27, M28, M32A, and M32B are NMOS transistors. The resistor R4 has a first terminal and a second terminal. The resistor R5 has a first terminal and a second terminal. The first current source 408 has a first terminal 410 and a second terminal 412. The second current source 414 has a first terminal 416 and a second terminal 418.

In the example of FIG. 5, the first terminal 364 of the cascode circuitry 362A receive INP_INT. The second terminal 366 of the cascode circuitry 362A receive INM_INT. The third and fourth terminals 368 and 370 of the cascode circuitry 362A receive current from an input transistor pair. The fifth terminal 372 of the cascode circuitry 362A is coupled to the third terminal 376 described in FIGS. 3 and 4. The sixth terminal 374 of the cascode circuitry 362A is coupled to the fourth terminal 378 described in FIGS. 3 and 4.

In the example of FIG. 5, the first terminal 364 of the cascode circuitry 362A is coupled to the control terminals of the transistors M23A, M23B, M24, M25, and M27. The second terminal 366 of the cascode circuitry 362A is coupled to the control terminals of the transistors M28, M30, M31, M32A, and M32B. The third terminal 368 of the cascode circuitry 362A is coupled to the first terminal of the resistor R4, the second terminal of the resistor M23A, and the first terminals of the transistors M24, M25, and M26. The second terminal of the transistor M24 is coupled to the second terminal of the resistor R4, the second terminal of the transistor M23B, and the body terminals of the transistors M25 and M26. The second terminals of the transistors M25 and M26 are coupled to the sixth terminal 374 of the cascode circuitry 362A. The fourth terminal 370 of the cascode circuitry 362A is coupled to the first terminal of the resistor R5, the second terminal of the transistor M32A, and the first terminals of the transistors M29, M30, and M31. The second terminal of the transistor M30 is coupled to the second terminal of the resistor R5, the second terminal of the transistor M32B, and the body terminals of the transistors M29 and M31. The second terminals of the transistors M29 and M31 are coupled to the fifth terminal 372 of the cascode circuitry 362A. The first terminals of the transistors M23A, M23B, M27, M28, M32A, and M32B are coupled to a power supply terminal (e.g., the power supply terminal 302). The second terminal of the transistor M27 is coupled to the control terminal of the transistor M26 and the first terminal 410 of the first current source 408. The second terminal 412 of the first current source 408 is coupled to ground or a ground terminal. The second terminal of the transistor M28 is coupled to the control terminal of the transistor M29 and the first terminal 416 of the second current source 414. The second terminal 418 of the second current source 414 is coupled to ground or a ground terminal.

In the example of FIG. 5, the cascode circuitry 362A operates to: receive INP_INT at the first terminal 364; receive INM_INT at the second terminal 366; receive currents from an input transistor pair at the third and fourth terminals 368 and 370; provide a first output current at the fifth terminal 372 responsive to the INM_INT, the receives currents, the operations of the transistors M28 to M31, M32A, and M32B, the resistor R5, and the second current source 414; provide a second output current at the sixth terminal 374 responsive to the INP_INT, the received currents, the operations of the transistors M23A, M23B, M24 to M27, the resistor R4, and the first current source 408. In some examples, the transistors M23A, M23B, M32A, and M32B operate as a clamping network to clamp low-to-high transients of INP_INT and/or INM_INT. The transistors M24 and M30 operate as a clamping network to clamp high-to-low transients of INP_INT and/or INM_INT. With the cascode circuitry 362A, the polarity of the first and second output currents from the cascode circuitry 362A track the polarity of INP_INT and INM_INT, even if INP_INT and/or INM_INT has fast rising edge transients (e.g., up to 5V/10 ns) and/or fast falling edge transients (e.g., up to 5V/10 ns).

In different examples, the IC circuitry 300 of FIG. 3, the IC circuitry 400 of FIG. 4, and the cascode circuitry 362A of FIG. 5 may be used separately or together. FIG. 6 is a schematic diagram showing other example IC circuitry 600 with transconductance amplifier stage circuitry (e.g., the input transistor pair M13 and M14, and the cascode circuitry 362A) and dynamic biasing circuitry (features of the dynamic biasing circuitry 320 in FIG. 3 and the dynamic biasing circuitry 420 in FIG. 4). In other words, the IC circuitry 600 combines the features of the IC circuitry 300 in FIG. 3, the IC circuitry 400 in FIG. 4, and the cascode circuitry 362A in FIG. 5. The IC circuitry 600 is an example of part of the amplifier 100 in FIG. 1, or part of the comparator 200 in FIG. 2.

In the example of FIG. 6, the IC circuitry 600 has the first terminal 364, the second terminal 366, the third terminal 368, and the fourth terminal 370 described in FIGS. 3 and 4. The first terminal 364 is an example of the first terminal 112 in FIG. 1, or the first terminal 212 in FIG. 2. The second terminal 366 is an example of the second terminal 114 in FIG. 1, or the second terminal 214 in FIG. 2. The third terminal 376 is an example of the third terminal 126 in FIG. 1, or the third terminal 226 in FIG. 2. The fourth terminal 378 is an example of the fourth terminal 128 in FIG. 1, or the fourth terminal 228 in FIG. 2.

In the example of FIG. 6, the IC circuitry 600 includes the transistors M3 to M21, M22A, M22B, M23A, M23B, M24 to M31, M32A, M32B, the first current source 304, the first current source 408, the second current source 414, the voltage drop circuitry 310, the capacitor C1, the resistors R3 to R5, the surge current suppressor 402. Each of the transistors M3 to M21, M22A, M22B, M23A, M23B, M24 to M31, M32A, M32B has a respective first terminal, a respective second terminal, and a respective control terminal. Each of the transistors M13, M14, M25, M26, M29, and M31 has a respective body terminal. In the example of FIG. 6, the transistors M3 to M21, M22A, M22B, M23A, M23B, M24 to M31, M32A, and M32B are NMOS or PMOS transistors as described in FIGS. 3 to 5. The first current source 304, the first current source 408, the second current source 414, the voltage drop circuitry 310, the capacitor C1, the resistors R3 to R5, and the surge current suppressor 402 have the same terminals as were described in FIGS. 3 to 5.

In the example of FIG. 6, the transistors M7 to M11, M16 to M19, and M21, the surge current suppressor 402, the resistor R3, and the capacitor C1 are dynamic biasing circuitry components (e.g., components of the dynamic biasing circuitry 140 in FIG. 1, or components of the dynamic biasing circuitry 240 in FIG. 2). The transistors M13 and M14 are an input transistor pair. The first current source 304, the voltage drop circuitry 310, and the transistors M6 and M20 regulate the switch voltage VSWN provided to the control terminals of the transistors M12 and M15. In some examples, the transistors M22A and M22B are NAT switches for input low-to-high transients. The transistors M23A, M23B, M24 to M31, M32A, and M32B, the first current source 408, the second current source 414, and the resistors R4 and R5 are components of the cascode circuitry 362A.

In the example of FIG. 6, the first terminals of the transistors M3, M4, M7, and M8 are coupled to the power supply terminal 302. The second terminal of the transistor M3 is coupled to a current source (not shown) and the control terminals of the transistors M3 and M4. The second terminal of the transistor M4 is coupled to the first terminal of the transistor M5 and the second terminal of the transistor M7. The second terminal of the transistor M8 is coupled to the first terminals of the transistors M9, M16, M18, and the first terminal 404 of the surge current suppressor 402. The second terminal of the transistor M8 is also coupled to the control terminals of the transistors M7 and M8. The second terminal of the transistor M16 is coupled to the first terminal of the transistor M17. The second terminal of the transistor M17 is coupled to the second terminal of the transistor M18, the second terminal of the first current source 304, the first terminal 312 of the voltage drop circuitry 310, and the body terminals of the transistors M13 and M14. The first terminal of the transistor M19 is coupled to the power supply terminal 302. The second terminal of the transistor M19 is coupled to the second terminal 314 of the voltage drop circuitry 310, the second terminal of the transistor M9, and the control terminals of the transistors M13 and M14. The control terminal of the transistor M16 receives INP_INT. The control terminal of the transistor M17 receives INM_INT. The control terminal of the transistor M18 receives the control voltage VSWN. The control terminal of the transistor M19 receives the CT voltage. The second terminal of the transistor M6 is coupled to ground or a ground terminal. The first terminal of the transistor M10 is coupled to the power supply terminal 302. The second terminal of the transistor M10 is coupled to the control terminal of the transistor M9 and the first terminal of the transistor M11. The second terminal of the transistor M11 is coupled to ground or a ground terminal. The control terminal of the transistor M11 is coupled to the first terminal of the capacitor C1, the second terminal of the resistor R3, and the second terminal of the transistor M20. The first terminal of the transistor M20 is coupled to the power supply terminal 302. The control terminal of the transistor M20 is coupled to the CT. The first terminal of the transistor M21 is coupled to the second terminal 406 of the surge current suppressor 402. The control terminal of the transistor M21 and the first terminal of the resistor R3 are coupled to the second terminal of the transistor M5 or the CT.

In the example of FIG. 6, the first terminal 364 of the cascode circuitry 362A is coupled to the control terminal of the transistor M13 and the second terminals of the transistors M12 and M22A. The control terminals of the transistors M22A and M22B are coupled to the CT. The second terminal 366 of the cascode circuitry 362A is coupled to the control terminal of the transistor M14 and the second terminals of the transistors M15 and M22B. The third terminal 368 of the cascode circuitry 362A is coupled to the second terminal of the transistor M13. The fourth terminal 370 of the cascode circuitry 362A is coupled to the second terminal of the transistor M14. The fifth terminal 372 of the cascode circuitry 362A is coupled to the third terminal 376 of the IC circuitry 600. The sixth terminal 374 of the cascode circuitry 362A is coupled to the fourth terminal 378 of the IC circuitry 600.

In the example of FIG. 6, the first terminal 364 of the cascode circuitry 362A is coupled to the control terminals of the transistors M23A, M23B, M24, M25, and M27. The second terminal 366 of the cascode circuitry 362A is coupled to the control terminals of the transistors M28, M30, M31, M32A, and M32B. The third terminal 368 of the cascode circuitry 362A is coupled to the first terminal of the resistor R4, the second terminal of the resistor M23A, and the first terminals of the transistors M24, M25, and M26. The second terminal of the transistor M24 is coupled to the second terminal of the resistor R4, the second terminal of the transistor M23, and the body terminals of the transistors M25 and M26. The second terminals of the transistors M25 and M26 are coupled to the sixth terminal 374 of the cascode circuitry 362A. The fourth terminal 370 of the cascode circuitry 362A is coupled to the first terminal of the resistor R5, the second terminal of the transistor M32A, and the first terminals of the transistors M29, M30, and M31. The second terminal of the transistor M30 is coupled to the second terminal of the resistor R5, the second terminal of the transistor M32B, and the body terminals of the transistors M29 and M31. The second terminals of the transistors M29 and M31 are coupled to the fifth terminal 372 of the cascode circuitry 362A. The first terminals of the transistors M23A, M23B, M27, M28, M32A, and M33B are coupled to the power supply terminal 302. The second terminal of the transistor M27 is coupled to the control terminal of the transistor M26 and the first terminal 410 of the first current source 408. The second terminal 412 of the first current source 408 is coupled to ground or a ground terminal. The second terminal of the transistor M28 is coupled to the control terminal of the transistor M29 and the first terminal 416 of the second current source 414. The second terminal 418 of the second current source 414 is coupled to ground or a ground terminal.

In the example of FIG. 6, the transistors M3 and M4 mirror ITAIL to the first terminal of the transistor M5. The control terminal of the transistor M5 receives Vclamp. ITAIL is combined with a bias current mirrored by the transistors M7 and M8, resulting in I_source3. The transistor M5 clamps I_source3 based on Vclamp. The clamped I_source3 provides current to the first terminals of the transistors M13 and M14 and results in the CT voltage.

In the example of FIG. 6, the CT voltage is used as a positive feedback to control the bias current. By clamping the resulting current, I_source3, stability is maintained with the positive feedback. In some examples, the CT voltage is provided to the control terminals of the transistors M6, M10 and M20, and the first terminal of the resistor R3. In the example of FIG. 6, the resistor R3 and the capacitor C1 operate as a low-pass filter. The filtered result is provided to the control terminal of the transistor M11. Together, the transistor M10 and M11 adjust the control voltage provided to the transistor M9. When the transistor M9 is turned on, bias current is mirrored to the first terminal of the transistor M5 via the transistors M7 and M8.

In the example of FIG. 6, the transistors M16, M17, M18, and M19 operate to adjust b_bias, which is provided to the body terminals of the transistor M13 and M14 to set the ground voltage for the transistors M13 and M14. The transistor M16 is controlled by INP_INT. The transistor M17 is controlled by INM_INT. The transistor M18 is controlled by the switch voltage VSWN. The transistor M19 is controlled by the CT voltage. In some examples, b_bias is also a function of the first current source 304, the voltage drop circuitry 310, and operations of the transistor M6. In some examples, the transistors M16 M17 operate as a clamping network for low-to-high transients in INP and/or INM (e.g., such transients are sensed at the CT). The transistors M9 and M10 operate as a clamping network for high-to-low transients in INP and/or INM (e.g., such transients may be sensed at the CT).

In the example of FIG. 6, the first terminal 364 of the cascode circuitry 362A receives INP. The second terminal 366 of the cascode circuitry 362A receives INM. INP is sensed as INP_INT based on the operations of the transistors M12 and M22A. INM is sensed as INM_INT based on the operations of the transistors M15 and M22B. In the example of FIG. 6, the transistors M12 and M15 are controlled using the control voltage VSWN, while the transistors M22A and M22B are controlled using the CT voltage.

In the example of FIG. 6, the cascode circuitry 362A operates to: receive INP_INT at the first terminal 364; receive INM_INT at the second terminal 366; receive currents based on the clamped I_source3 at the third terminal 368 and the fourth terminal 370 and based on the input pair M13 and M14; provide the first output current at the fifth terminal 372 responsive to the INM_INT, the received currents, the operations of the transistors M28 to M31, M32A, M32B, the resistor R5, and the second current source 414; provide the second output current at the sixth terminal 374 responsive to the INP_INT, the received currents, the operations of the transistors M23A, M23B, M24 to M27, the resistor R4, and the first current source 408. In some examples, the transistors M23A, M23B, M32A, and M32B operate as a clamping network to clamp low-to-high transients of INP_INT and/or INM_INT. The transistors M24 and M30 operate as a clamping network to clamp the body terminals of cascode transistors (e.g., transistors M25, M26, M29, and M31).

In some examples, the transistors M12, M15, M18, M21, M23A, M23B, M27, M28, M32A, and M32B have a higher voltage rating (e.g., 40V) and are drain extended NMOS (DENMOS) transistors. In such examples, the transistors M9, M10, M16, M17, M19, M20, M22A, and M22B have a higher voltage rating (e.g., 40V) and are NAT transistors. Also, the transistors M5, M11, M25, M26, M29, and 31 have a higher voltage rating (e.g., 40V) and are drain extended PMOS (DEPMOS) transistors. Also, the transistors M3, M4, M6, M7, M8, M13, M14, M24 and M30 have a lower voltage rating (e.g., 5V) and are complementary metal-oxide semiconductor (CMOS) transistors.

With dynamic biasing circuitry, the IC circuitry 600 is able to add bias current to ITAIL based on transients in INP (e.g., INP1 in FIG. 1, or INP2 in FIG. 2) at the first terminal 364, transients in INM (e.g., INM1 in FIG. 1, or INM2 in FIG. 2) at the second terminal 366, and/or resulting transients at target terminals (e.g., the CT). The bias current combined with ITAIL results in I_source3. I_source3 is clamped using the transistor M5. The clamped I_source3 is provided to the cascode circuitry 362A via the input transistor pair (transistors M13 and M14). In some examples, the transistor M13 is controlled based on the difference between INP_INT and b_bias. The transistor M14 is controlled based on the difference between INM_INT and b_bias.

In some examples, IC circuitry (e.g., the IC circuitry 300 of FIG. 3, the IC circuitry 400 of FIG. 4, or the IC circuitry 600 of FIG. 6) includes dynamic biasing circuitry and clamping network circuitry to overcome the effects of parasitic capacitance at target terminals (e.g., the CT and the b_bias terminal). In some examples, the dynamic biasing circuitry boosts a tail current (e.g., ITAIL plus I_source1 or I_source2 or I_source3) responsive to a fast transition in INP or INM to avoid insufficient current at the input without affecting the steady state quiescent current. In some examples, IC circuitry includes: sensing field-effect transistors (FETs) and a high voltage capacitor to detect INP or INM transitions; current mirrors to boost the tail current; and current limit circuitry. Such IC circuitry and related transconductance amplifier stages benefit from low quiescent power and minimal area impact compared to other transconductance amplifier stage topologies. By quickly responding to INM or INP transition edges, output glitches due to inconsistent tracking of INM and INP polarity due to parasitic capacitances. In some examples, the b_bias terminal is the slowest terminal of a transconductance amplifier stage as more transistor backgates are tied to the b_bias terminal, resulting in a larger parasitic capacitance. With the dynamic biasing circuitry and transient response circuitry (e.g., clamping networks, discharge circuitry, etc.), the polarity of output currents of a transconductance amplified stages accurately tracks the polarity of INM and/or INP to avoid such glitches.

In some examples, dynamic biasing circuitry senses the voltage at the slowest terminal (e.g., the CT or the b_bias terminal) and turns on clamping while the minimum of INP_INT and INM_INT is unable to track b_bias. In a steady state condition, b_bias is greater than the minimum of INP_INT and INM_INT, and clamping is off. In response to a rising edge transient of INP or INM, the parasitic capacitance at the b_bias terminal slows transitions at the terminal and clamping is turned on while the dynamic biasing circuitry pumps current to the tail terminal (e.g., the first terminal of the transistor M5). With such dynamic biasing circuitry, the polarity of output currents of a transconductance amplifier stage more consistently track the polarity of INP and/or INM, which avoids glitches (dead zones) in a related comparator output or amplifier output.

In some examples, a transconductance amplifier stage uses dynamic biasing circuitry with a lowpass filter (LPF) circuit to account for falling edge transitions are parasitic input capacitance. In steady state condition, a source follower, driven by the LPF circuit, drives an NAT DENMOS clamp, which is off. During steady state, the DENMOS clamp (e.g., the transistor M9) does not react. During a falling edge transition, the control terminal of the DENMOS clamp decreases slowly whereas the source terminal decreases faster, which turns on the DENMOS clamp and provided current. Such clamping is helpful when the inputs cross over (INM goes high and INP goes low or vice versa). The related current surge is used to feed the parasitic capacitance of an input transistor pair (e.g., the transistors M13 and M14 in FIGS. 3, 4, and 6), ensuring there is adequate current flow through the input transistor pair during transitions. In this manner, glitches in an amplifier or comparator output due to falling edge INP or INM transitions are avoided.

In some examples, dynamic biasing circuitry of a transconductance amplifier stage uses clamps to overcome the effects of back-gate and isolation parasitic capacitance for rising transitions in INP or INM. In a steady state condition, b_bias is higher than the gate connections of all transistors used as clamps for that terminal (i.e., b_bias is greater than the minimum of INP_INT and INM_INT, so clamping is turned off. However, during rising edge transitions, the clamps sense the slowest terminal (b_bias) and the clamp network turns on. In some examples, a combination of bias levels are triggered (Vt and bias voltage dependent) and clamped. Some of the current flowing through the clamp network is fed back to the tail terminal.

In some examples, a transconductance amplifier stage uses a low pass filter based clamp biased with the tail terminal, where a bounded current is fed back to the CT. Such circuitry enables INM or INP transients for step inputs (where the backgate bias does not move enough to trigger the existing clamps). All the currents fed back to the tail compensate for any losses of tail current in the signal path, ensuring limited impact to current steered by the input pair.

In some examples, a transconductance amplifier stage operates so that gates of the input transistor pair track the input signal with the default input DENMOS switch, which may be turned off due to slow propagation of VSWN. In some examples, a small input NAT (0-Vt) DENMOS device is used so that parallel stays on. This comes at the cost of slightly higher, but acceptable, input leakage.

As the cascode backgates (e.g., the body terminals of the transistors M25, M26, M29, and M31 in FIG. 4) have parasitic capacitance that draw current away for low-to-high transients. In some examples, a resistor (e.g., the resistors R4 or R5 in FIG. 4) is placed to isolate the source terminal from the back-gate, thus limiting the transient current needed to charge the latter. In some examples, IC circuitry includes DENMOS clamp circuitry at cascode terminals to pump dynamic current and charge the Cgs capacitance and the backgate capacitance of the cascodes while the input ramp begins.

During low to high transients, the DENMOS clamp circuitry charges up the parasitic capacitance at both back-gate and the source independently and spontaneously minimize signal current diversion and ensure signal currents maintain the right polarity to stay functional. When an input (e.g., INP and/or INM) ramps down quickly, the cascode backgate stays high, which may result in functional issues as cascode transistors (e.g., the transistor M25, M26, M29, and M31) can lose margin with the cascode threshold voltage (Vt) becoming higher. To prevent this from happening a switch (e.g., the transistors M24 or M30 in FIGS. 4 and 6) turns on and helps the cascode body to discharge faster, thus ensuring cascode transistors (e.g., the transistors M25, M26, M29, and M31) operate normally during this phase.

If the capacitance at the cascode backgate becomes too large, the source to back-gate voltage difference forward biases that junction during low to high transients, which bypasses the resistor (e.g., R4 and R5 in FIGS. 4 and 6) and charges that capacitance directly. The result is signal current being diverted. Accordingly, cascode circuitry may include other DENMOS clamps (e.g., the transistors M23A, M23B, M32A, and M33B) to charge up the cascode body spontaneously, ensuring signal currents maintain the right polarity to stay functional.

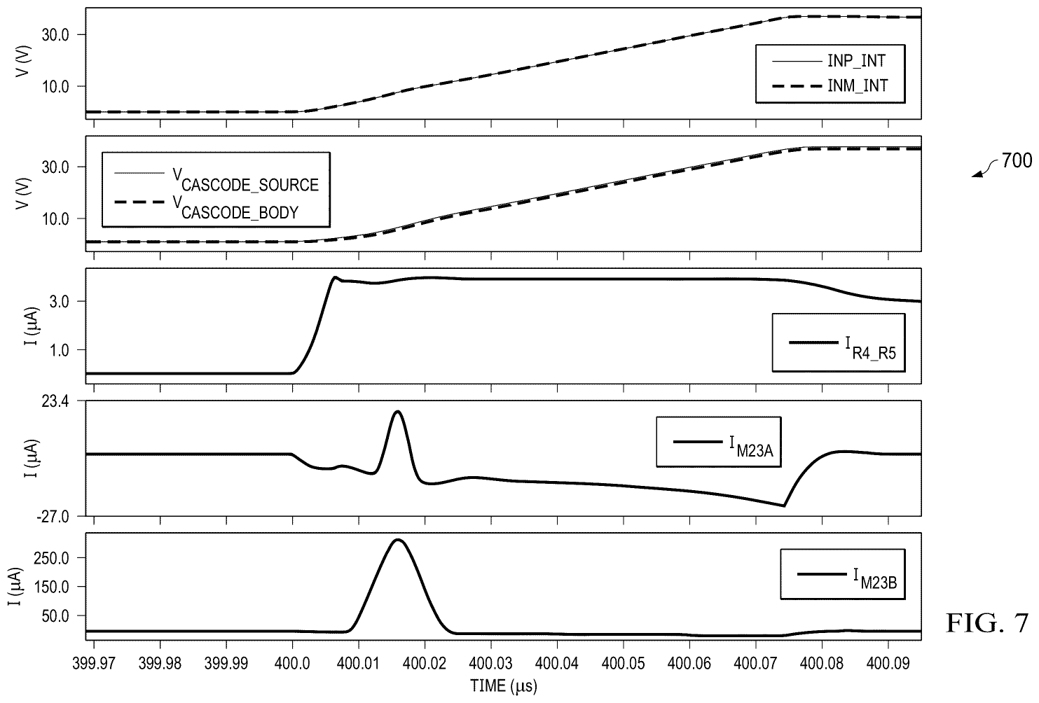

FIG. 7 is a graph 700 showing voltages and currents of an example transconductance amplifier stage. As shown, the graph 700 includes voltage waveforms for INP_INT, INM_INT, a cascode source voltage (V_{CASCODE_SOURCE}), a cascode body voltage (V_{CASCODE_BODY}), a current through R4 and R5 (I_{R4_R5}), a current through the transistor M23A (I_{M23A}), and a current through the transistor M23B (I_{M23B}). In the example of FIG. 7, INP_INT, INM_INT, V_{CASCODE_SOURCE}, and V_{CASCODE_BODY} ramp up together from 0 to approximately 36V. When INP_INT, INM_INT, V_{CASCODE_SOURCE}, and V_{CASCODE_BODY} begin to ramp up, I_{R4_R5} increases from 0V to approximately 4 uA and is clamped as needed by the transistors M23A, M23B, M32A, and M32B turning on as represented by the fluctuations in I_{M23A} and I_{M23A}. In some examples, IC circuitry (e.g., the IC circuitry 300 in FIG. 3, the IC circuitry 400 in FIG. 4, or the IC circuitry 600 in FIG. 6) includes dynamic biasing circuitry and cascode circuitry with transient response circuitry so that V_{CT} and V_{BODY} closely track INP_INT and INM_INT, which help avoid inconsistency in the polarity of the output currents from a transconductance amplifier stage and related glitches in an amplifier or comparator.

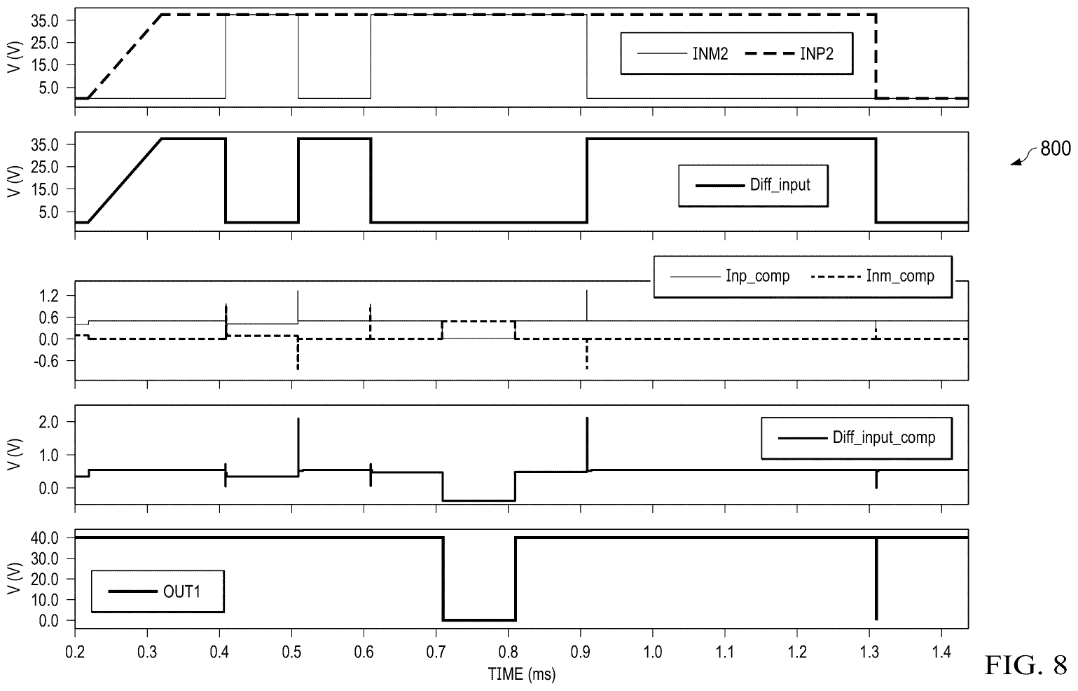

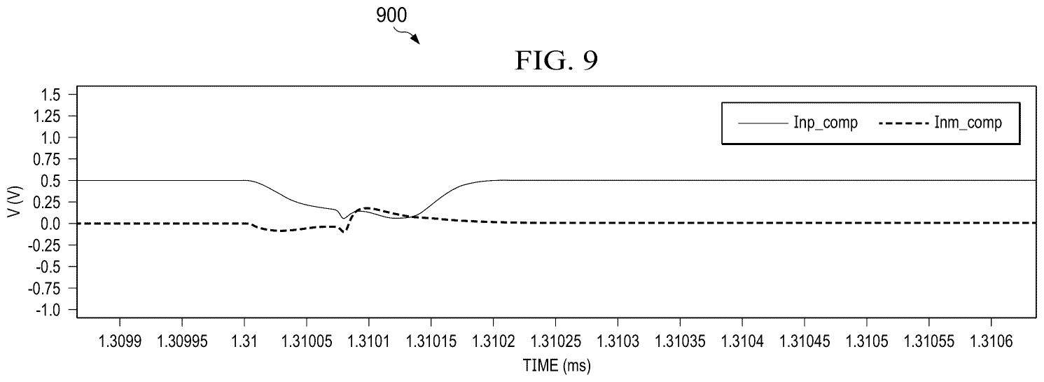

FIGS. 8 and 9 include graphs 800 and 900 showing voltages of an example comparator without the dynamic biasing circuitry (e.g., without the dynamic biasing circuitry 140 in FIG. 1, the dynamic biasing circuitry 140 in FIG. 2, without the dynamic biasing circuitry 320 in FIG. 3, without the dynamic biasing circuitry 420 in FIG. 4, and/or without the dynamic biasing circuitry in FIG. 6) and/or without transient response circuitry (e.g., without the transistors M22A and M22B in FIG. 6, without clamping networks of the cascode circuitry 362A in FIGS. 5 and 6, and/or without discharge circuitry of the cascode circuitry 362A in FIGS. 5 and 6).

In the graph 800 of FIG. 8, waveforms for INM2, INP2, a differential input result (Diff_input), input pair output for INP (Inp_comp), input pair output for INM (Inm_comp), a transconductance amplifier stage differential output (Diff_input_comp), and OUT1 are represented. In the example of FIG. 8, Diff_input is the difference between INM2 and INP2. Diff_input_comp is the difference between Inp_comp and Inm_comp. OUT1 is the output of the comparator. As shown in graph 800 of FIG. 8, OUT1 includes a glitch at approximately 1.3 ms. The glitch in OUT1 is due to Inp_comp and Inm_comp flipping polarities during a fast falling edge transient as represented in graph 900 of FIG. 9.

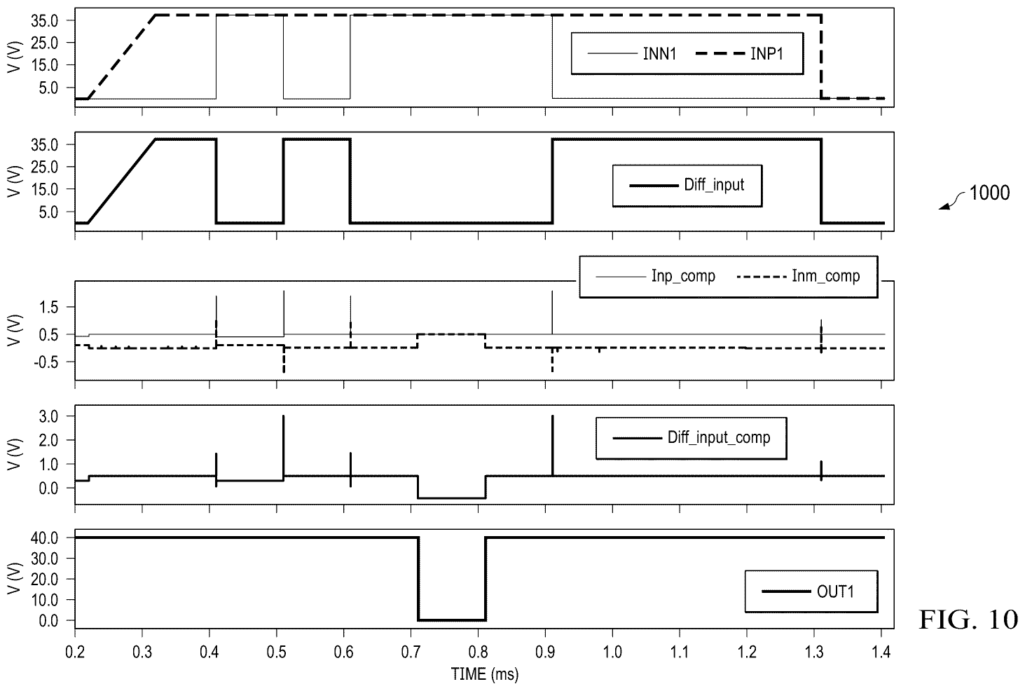

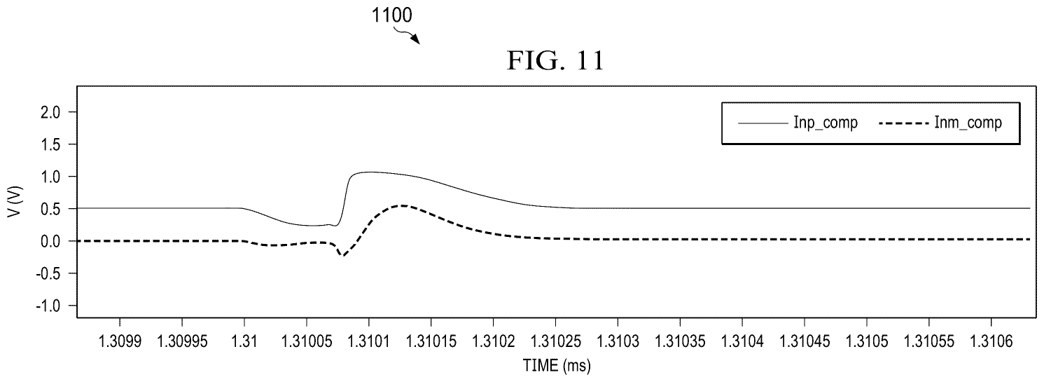

FIGS. 10 and 11 include graphs 1000 and 1100 showing voltages related to a falling edge transition for an example comparator with dynamic biasing circuitry (e.g., with the dynamic biasing circuitry 140 in FIG. 1, with the dynamic biasing circuitry 140 in FIG. 2, with the dynamic biasing circuitry 320 in FIG. 3, with the dynamic biasing circuitry 420 in FIG. 4, and/or with the dynamic biasing circuitry in FIG. 6) and/or with transient response circuitry (e.g., with the transistors M22A and M22B in FIG. 6, with clamping networks of the cascode circuitry 362A in FIGS. 5 and 6, and/or with discharge circuitry of the cascode circuitry 362A in FIGS. 5 and 6). In the graph 1000, waveforms for INM2, INP2, Diff_input, Inp_comp, Inm_comp, Diff_input_comp, and OUT1 are represented. In the example of FIG. 10, Diff_input is the difference between INM2 and INP2. Diff_input_comp is the difference between Inp_comp and Inm_comp. OUT1 is the output of the comparator. As shown in graph 1000 of FIG. 10, glitches in OUT1 are avoided. In some examples, avoiding glitches in OUT1 as in the example of FIG. 10 is based on use of dynamic biasing circuitry and/or transient response circuitry to ensure Inp_comp and Inp_comp maintain their respective polarities during a fast falling edge transient as represented in graph 1100 of FIG. 11.

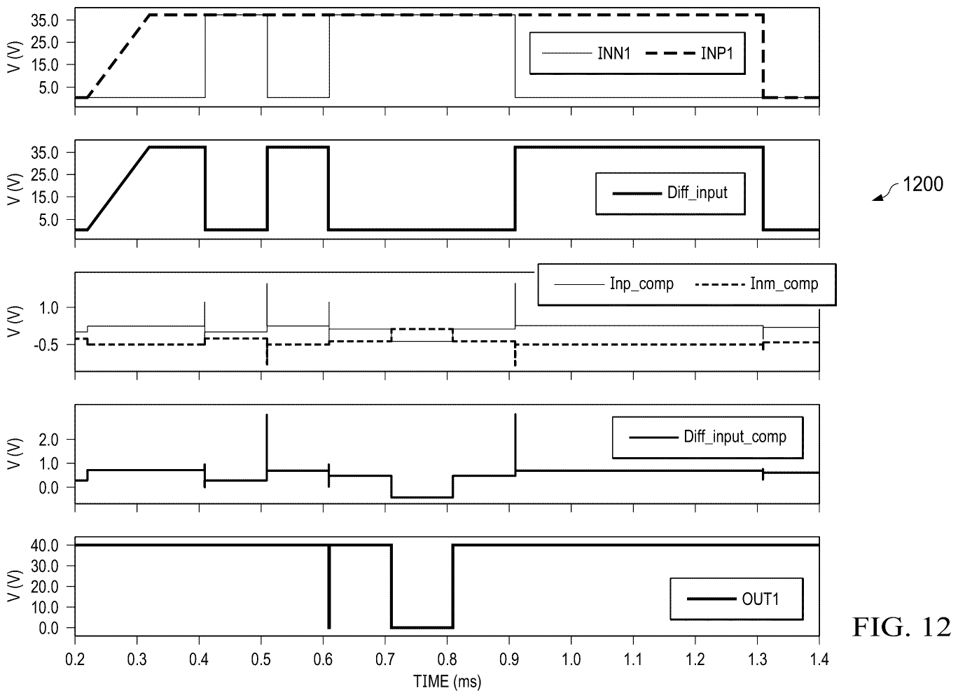

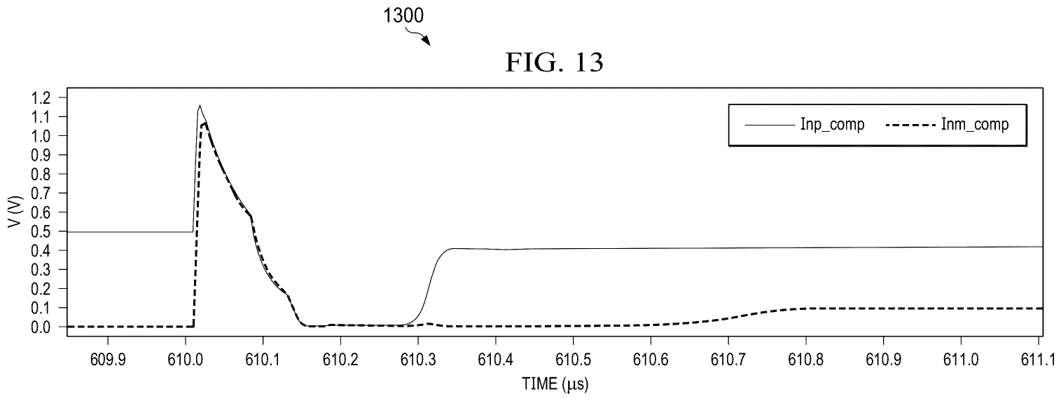

FIGS. 12 and 13 include graphs 1200 and 1300 showing voltages related to a rising edge transition for an example comparator without dynamic biasing circuitry (e.g., without the dynamic biasing circuitry 140 in FIG. 1, without the dynamic biasing circuitry 140 in FIG. 2, without the dynamic biasing circuitry 320 in FIG. 3, without the dynamic biasing circuitry 420 in FIG. 4, and/or without the dynamic biasing circuitry in FIG. 6) and/or without transient response circuitry (e.g., without the transistors M22A and M22B in FIG. 6, without clamping networks of the cascode circuitry 362A in FIGS. 5 and 6, and/or without discharge circuitry of the cascode circuitry 362A in FIGS. 5 and 6). In the graph 1200 of FIG. 12, waveforms for INM2, INP2, Diff_input, Inp_comp, Inm_comp, Diff_input_comp, and OUT1 are represented. In the example of FIG. 12, Diff_input is the difference between INM2 and INP2. Diff_input_comp is the difference between Inp_comp and Inm_comp. OUT1 is the output of the comparator. As shown in graph 1200 of FIG. 12, OUT1 includes a glitch at approximately 0.6 ms. The glitch in OUT1 is due to Inp_comp and Inp_comp flipping polarities during a fast rising edge transient as represented in graph 1300 of FIG. 13.

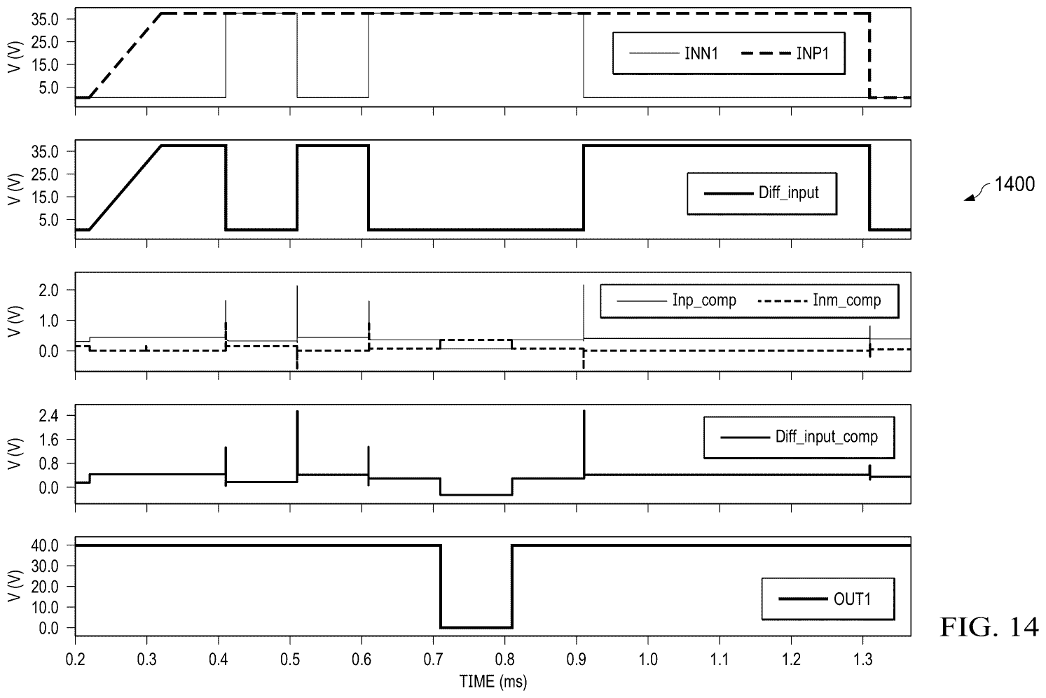

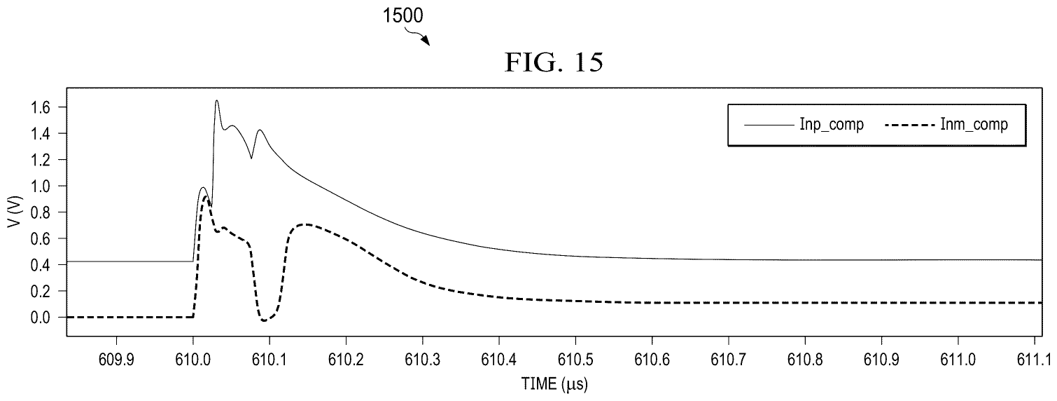

FIGS. 14 and 15 include graphs 1400 and 1500 showing voltages related to a rising edge transition for an example comparator with dynamic biasing circuitry (e.g., with the dynamic biasing circuitry 140 in FIG. 1, with the dynamic biasing circuitry 140 in FIG. 2, the dynamic biasing circuitry 320 in FIG. 3, with the dynamic biasing circuitry 420 in FIG. 4, and/or with the dynamic biasing circuitry in FIG. 6) and/or with transient response circuitry (e.g., with the transistors M22A and M22B in FIG. 6, with clamping networks of the cascode circuitry 362A in FIGS. 5 and 6, and/or with discharge circuitry of the cascode circuitry 362A in FIGS. 5 and 6). In the graph 1400 of FIG. 14, waveforms for INM2, INP2, Diff_input, Inp_comp, Inm_comp, Diff_input_comp, and OUT1 are represented. In the example of FIG. 14, Diff_input is the difference between INM2 and INP2. Diff_input_comp is the difference between Inp_comp and Inm_comp. OUT1 is the output of the comparator. As shown in graph 1400 of FIG. 15, glitches in OUT1 are avoided. Avoiding glitches in OUT1 as in the example of FIG. 14 is based on use of dynamic biasing circuitry and/or cascode circuitry with clamping to ensure Inp_comp and Inp_comp maintain their respective polarities during a fast rising edge transient as represented in graph 1500 of FIG. 15.

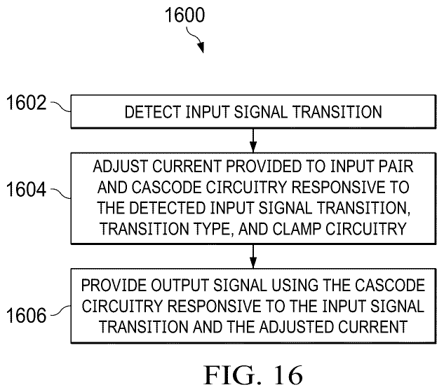

FIG. 16 is a flowchart showing an example control method 1600 for a transconductance amplifier stage method. The control method 1600 may be performed for the transconductance amplifier stage 110 of FIG. 1, the transconductance amplifier stage 210 of FIG. 2, the transconductance amplifier stage circuitry of FIG. 3, the transconductance amplifier stage circuitry of FIG. 4, or the transconductance amplifier stage circuitry of FIG. 6). As shown, the control method 1600 includes detecting an input signal transition at block 1602. In some examples, detecting the input signal transition in block 1602 is performed by dynamic biasing circuitry (e.g., the dynamic biasing circuitry 140 in FIG. 1, the dynamic biasing circuitry 140 in FIG. 2, the dynamic biasing circuitry 320 in FIG. 3, the dynamic biasing circuitry 420 in FIG. 4, and/or the dynamic biasing circuitry in FIG. 6) monitoring the voltage at a target terminal.

At block 1604, current provided to an input transistor pair and/or cascode circuitry of the transconductance amplifier stage is adjusted responsive to the detected input signal transition, transition type, and clamp circuitry (or other transition response circuitry). In some examples, In some examples, providing current as in block 1604 is performed by dynamic biasing circuitry (e.g., the dynamic biasing circuitry 140 in FIG. 1, the dynamic biasing circuitry 140 in FIG. 2, the dynamic biasing circuitry 320 in FIG. 3, the dynamic biasing circuitry 420 in FIG. 4, and/or the dynamic biasing circuitry in FIG. 6).

At block 1606, an output signal is provided using the cascode circuitry responsive to the input signal transition and the adjusted current. In some examples, output currents are provided by the cascode circuitry responsive to the input signal transition, the adjusted current, and transient response circuitry (e.g., with the transistors M22A and M22B in FIG. 6, with clamping networks of the cascode circuitry 362A in FIGS. 5 and 6, and/or with discharge circuitry of the cascode circuitry 362A in FIGS. 5 and 6). With the control method 1600, the polarity of outputs currents of a transconductance amplifier stage accurately track the polarity of input signals (e.g., INP and INM), even for fast rising edge transitions (e.g., up 5V/10 ns) and/or fast falling edge transitions (e.g., up 5V/10 ns).

In some examples, an IC (e.g., an IC related to the amplifier 100 in FIG. 1, an IC related to the comparator 200 of FIG. 2, the IC circuitry 300 in FIG. 3, the IC circuitry 400 in FIG. 4, or the IC circuitry 600 in FIG. 6) includes: a first transistor (e.g., the transistor M13) having a first terminal, a second terminal, and a control terminal; a second transistor (e.g., the transistor M14) having a first terminal, a second terminal, and a control terminal; and cascode circuitry (e.g., the cascode circuitry 362 in FIGS. 3 and 4, or the cascode circuitry 362A in FIGS. 5 and 6). The cascode circuitry has a first terminal (e.g., the first terminal 364 in FIGS. 3, 4, 5, and 6), a second terminal (e.g., the second terminal 366 in FIGS. 3, 4, 5, and 6), a third terminal (e.g., the third terminal 368 in FIGS. 3, 4, 5, and 6), a fourth terminal (e.g., the fourth terminal 370 in FIGS. 3, 4, 5, and 6), a fifth terminal (e.g., the fifth terminal 372 in FIGS. 3, 4, 5, and 6), and a sixth terminal (e.g., the sixth terminal 374 in FIGS. 3, 4, 5, and 6). The first terminal of the cascode circuitry is coupled to the control terminal of the first transistor. The second terminal of the cascode circuitry is coupled to the control terminal of the second transistor. The third terminal of the cascode circuitry is coupled to the second terminal of the first transistor. The fourth terminal of the cascode circuitry is coupled to the second terminal of the second transistor. In such examples, the IC also includes dynamic biasing circuitry (e.g., the dynamic biasing circuitry 140 in FIG. 1, the dynamic biasing circuitry 240 in FIG. 2, the dynamic biasing circuitry 320 in FIG. 3, the dynamic biasing circuitry 420 in FIG. 4, or the dynamic biasing circuitry in FIG. 6) having a first terminal (e.g., the first terminal 141 in FIG. 1, the first terminal 241 in FIG. 2, the first terminal 322 in FIG. 3, the first terminal 422 in FIG. 4, or CT, the first terminal of the resistor R3, or the control terminal of the transistor M21 in FIG. 6) and a second terminal (e.g., the second terminal 142 in FIG. 1, the second terminal 242 in FIG. 2, the fourth terminal 328 in FIG. 3, the fourth terminal 428 in FIG. 4, or the second terminal of the transistor M7 in FIG. 6). The first terminal of the dynamic biasing circuitry is coupled to the first terminals of the first and second transistors.

In some examples, the IC includes switch voltage circuitry (e.g., the first current source 304 in FIGS. 3, 4, and 6, the voltage drop circuitry 310 in FIGS. 3, 4, and 6, and/or the transistor M6 in FIGS. 3, 4, and 6). In such examples, the IC also includes: a third transistor (e.g., the transistor M12 in FIGS. 3, 4, and 6) having a first terminal, a second terminal, and a control terminal, the second terminal of the third transistor coupled to the first terminal of the cascode circuitry, and the control terminal of the third transistor coupled to the switch voltage circuitry; and a fourth transistor (e.g., the transistor M15 in FIGS. 3, 4, and 6) having a first terminal, a second terminal, and a control terminal, the second terminal of the fourth transistor coupled to the second terminal of the cascode circuitry, and the control terminal of the fourth transistor coupled to the switch voltage circuitry.

In some examples, the IC includes a fifth transistor (e.g., the transistor M5 in FIGS. 3,4, and 6) having a first terminal, a second terminal, and a control terminal. The first terminal of the fifth transistor is coupled to the second terminal of the dynamic biasing circuit, and the second terminal of the fifth transistor is coupled to the first terminals of the first and second transistors.

In some examples, the dynamic biasing circuitry includes an LPF circuit coupled to the first terminal of the dynamic biasing circuitry. In some examples, the dynamic biasing circuitry includes a fifth transistor (e.g., the transistor M11 in FIG. 3, the transistor M21 in FIGS. 4 and 6) having a first terminal, a second terminal, and a control terminal. The control terminal of the fifth transistor is coupled to the LPF circuit. In such examples, the dynamic biasing circuitry includes a sixth transistor (e.g., the transistor M9 in FIG. 3) having a first terminal, a second terminal, and a control terminal. The control terminal of the sixth transistor is coupled to the first terminal of the fifth transistor. In some examples, the dynamic biasing circuitry includes a surge current suppressor (e.g., the surge current suppressor 402 in FIG. 4) having a first terminal (e.g., the first terminal 404 in FIG. 4) and a second terminal (e.g., the second terminal 406 in FIG. 4). The second terminal of the surge current suppressor is coupled to the first terminal of the fifth transistor. In some examples, the dynamic biasing circuitry includes a current mirror (e.g., the transistors M7 and M8) having a first terminal (e.g., the second terminal of the transistor M8) and a second terminal (e.g., the second terminal of the transistor M7). The first terminal of the current mirror is coupled to the first terminal of the fifth transistor. In some examples, each of the first and second transistors has a respective body terminal, and the dynamic biasing circuitry is configured to provide a bias voltage (e.g., b_bias herein) to the body terminals of the first and second transistors.

In some examples, a circuit (e.g., the amplifier 100 in FIG. 1, the comparator 200 in FIG. 2, the IC circuitry 300 in FIG. 3, the IC circuitry 400 in FIG. 4, the IC circuitry 600 in FIG. 6) includes a transconductance amplifier stage (e.g., the transconductance amplifier stage 110 in FIG. 1, the transconductance amplifier stage 210 in FIG. 2, the transconductance amplifier stage circuitry in FIGS. 3, 4, and 6). An example transconductance amplifier stage includes the input transistor pair with transistors M13 and M14 in FIGS. 3, 4, and 6, the cascode circuitry 362 in FIGS. 3, and 4, and/or the cascode circuitry 362A in FIG. 6.

In some examples, the transconductance amplifier stage includes a first transistor (e.g., the transistor M13 in FIGS. 3, 4, and 6) having a first terminal, a second terminal, and a control terminal; a second transistor e.g., the transistor M14 in FIGS. 3, 4, and 6) having a first terminal, a second terminal, and a control terminal; and cascode circuitry (e.g., the cascode circuitry 120 in FIG. 1, the cascode circuitry 220 in FIG. 2, the cascode circuitry 362 in FIGS. 3 and 4, or the cascode circuitry 362A in FIG. 6). The cascode circuitry has a first terminal (e.g., the first terminal 364 in FIGS. 3, 4, 5, and 6), a second terminal (e.g., the second terminal 366 in FIGS. 3, 4, 5, and 6), a third terminal (e.g., the third terminal 368 in FIGS. 3, 4, 5, and 6), a fourth terminal (e.g., the fourth terminal 370 in FIGS. 3, 4, 5, and 6), a fifth terminal (e.g., the fifth terminal 372 in FIGS. 3, 4, 5, and 6), and a sixth terminal (e.g., the sixth terminal 374 in FIGS. 3, 4, 5, and 6). The first terminal of the cascode circuitry is coupled to the second terminal of the first transistor. The second terminal of the cascode circuitry is coupled to the second terminal of the second transistor. In such examples, the circuit includes dynamic biasing circuitry coupled to the first terminals of first and second transistors. The dynamic biasing circuitry operates to: detect a voltage transient at a target terminal (e.g., the CT or the b_bias terminal in FIGS. 3, 4, and 6)) of the transconductance amplifier stage; adjust a bias current (e.g., the bias current output from the current mirror based transistors M7 and M8) responsive to the voltage transient; and provide the adjusted bias current to the first terminals of the first and second transistors (e.g., a first bias current is added to ITAIL in FIG. 3, resulting in I_source1, a second bias current is added to ITAIL in FIG. 4, resulting in I_source2, or a third bias current is added to ITAIL in FIG. 6, resulting in I_source3).

In some examples, the circuit includes a gain stage (e.g., the gain stage 150 in FIG. 1) having a first terminal, a second terminal, a third terminal, and a fourth terminal, the first terminal of the gain stage coupled to the fifth terminal of the cascode circuitry, and the second terminal of the gain stage coupled to the sixth terminal of the cascode circuitry. In some examples, the circuit include an intermediate stage (e.g., the intermediate stage 162 in FIG. 1) and an output stage (e.g., the output stage 172 in FIG. 1), wherein the transconductance amplifier stage, the gain stage, the intermediate stage, and the output stage are stages of an amplifier (e.g., the amplifier 100 in FIG. 1).

In some examples, the circuit includes a differential cross-coupled stage (e.g., the differential cross-coupled stage 250 in FIG. 2), a differential to single-ended stage (e.g., differential to single-ended stage 260 in FIG. 2), and a level shift and drivers stage (e.g., the left shift and drivers stage 268 in FIG. 2), wherein the transconductance amplifier stage, the gain stage, the differential cross-coupled stage, the differential to single-ended stage, and the level shift and drivers stage are stages of a comparator (e.g., the comparator 200 in FIG. 2).

In some examples, the dynamic biasing circuitry (e.g., the dynamic biasing circuitry 140 in FIG. 1, the dynamic biasing circuitry 240 in FIG. 2, the dynamic biasing circuitry 420 in FIG. 4, or the dynamic biasing circuitry in FIG. 6) is configured to: detect a low-to-high voltage transient at the target terminal (e.g., the CT or the b_bias terminal); and adjust the bias current with a first adjustment responsive to the low-to-high voltage transient. In some examples, the dynamic biasing circuitry (e.g., the dynamic biasing circuitry 140 in FIG. 1, the dynamic biasing circuitry 240 in FIG. 2, or the dynamic biasing circuitry in FIG. 6) is configured to: detect a high-to-low voltage transient at the target terminal; and adjust the bias current with a second adjustment responsive to the high-to-low voltage transient, the second adjustment different than the first adjustment.

In some examples, the circuit includes: a third transistor (e.g., the transistor M12 in FIGS. 3, 4, and 6); a fourth transistor (e.g., the transistor M15 in FIGS. 3, 4, and 6); a fifth transistor (e.g., the transistor M22A in FIG. 6); and a sixth transistor (e.g., the transistor M22N in FIG. 6). The third transistor has a first terminal, a second terminal, and a control terminal. The second terminal of the third transistor is coupled to the first terminal of the cascode circuitry. The fourth transistor has a first terminal, a second terminal, and a control terminal. The second terminal of the fourth transistor is coupled to the second terminal of the cascode circuitry. The fifth transistor has a first terminal, a second terminal, and a control terminal. The first terminal of the fifth transistor coupled to the first terminal of the third transistor. The second terminal of the fifth transistor coupled to the second terminal of the third transistor. The fifth transistor is a native transistor (i.e., with near zero threshold). The sixth transistor has a first terminal, a second terminal, and a control terminal. The first terminal of the sixth transistor is coupled to the first terminal of the fourth transistor. The second terminal of the sixth transistor coupled to the second terminal of the fourth transistor. The sixth transistor is a native transistor (i.e., with near zero threshold).

In some examples, the cascode circuitry includes transient response circuitry. The transient response circuitry includes a clamping network (e.g., the transistors M23A, M23B, M32A, and M32B), and discharge circuitry (e.g., the transistors M24 and M30 in FIGS. 5 and 6).

In some examples, a circuit (e.g., the amplifier 100 in FIG. 1, the comparator 200 in FIG. 2, the IC circuitry 300 in FIG. 3, the IC circuitry 400 in FIG. 4, the IC circuitry 600 in FIG. 6) includes a transconductance amplifier stage (e.g., the transconductance amplifier stage 110 in FIG. 1, the transconductance amplifier stage 210 in FIG. 2, the transconductance amplifier stage circuitry in FIGS. 3, 4, and 6). An example transconductance amplifier stage includes the input transistor pair with transistors M13 and M14 in FIGS. 3, 4, and 6, the cascode circuitry 362 in FIGS. 3, and 4, and/or the cascode circuitry 362A in FIG. 6.

In some examples, the transconductance amplifier stage includes: a first transistor (e.g., the transistor M13 in FIGS. 3, 4, and 6) having a first terminal, a second terminal, and a control terminal; a second transistor (e.g., the transistor M14 in FIGS. 3, 4, and 6) having a first terminal, a second terminal, and a control terminal; a third transistor (e.g., the transistor M12 in FIGS. 3, 4, and 6) having a first terminal, a second terminal, and a control terminal; a fourth transistor (e.g., the transistor M15 in FIGS. 3, 4, and 6) having a first terminal, a second terminal, and a control terminal; and a fifth transistor (e.g., the transistor M5 in FIGS. 3, 4, and 6) having a first terminal, a second terminal, and a control terminal, the second terminal of the fifth transistor coupled to the first terminals of the first and second transistors. In such examples, the transconductance amplifier stage also includes cascode circuitry (e.g., the cascode circuitry 120 in FIG. 1, the cascode circuitry 220 in FIG. 2, the cascode circuitry 362 in FIGS. 3 and 4, or the cascode circuitry 362A in FIG. 6). The cascode circuitry has a first terminal (e.g., the first terminal 364 in FIGS. 3, 4, 5, and 6), a second terminal (e.g., the second terminal 366 in FIGS. 3, 4, 5, and 6), a third terminal (e.g., the third terminal 368 in FIGS. 3, 4, 5, and 6), a fourth terminal (e.g., the fourth terminal 370 in FIGS. 3, 4, 5, and 6), a fifth terminal (e.g., the fifth terminal 372 in FIGS. 3, 4, 5, and 6), and a sixth terminal (e.g., the sixth terminal 374 in FIGS. 3, 4, 5, and 6). The first terminal of the cascode circuitry is coupled to the control terminal of the first transistor and the second terminal of the third transistor. The second terminal of the cascode circuitry is coupled to the control terminal of the second transistor and the second terminal of the fourth transistor. The third terminal of the cascode circuitry is coupled to the second terminal of the first transistor. The fourth terminal of the cascode circuitry is coupled to the second terminal of the second transistor.

In some examples, the circuit also includes dynamic biasing circuitry (e.g., the dynamic biasing circuitry 140 in FIG. 1, the dynamic biasing circuitry 240 in FIG. 2, the dynamic biasing circuitry 420 in FIG. 4, or the dynamic biasing circuitry in FIG. 6) having a first terminal (e.g., the first terminal 141 in FIG. 1, the first terminal 241 in FIG. 2, the first terminal 322 in FIG. 3, the first terminal 422 in FIG. 4, or the CT, the first terminal of the resistor R3, of the control terminal of the transistor M21 in FIG. 6) and a second terminal (e.g., the second terminal 142 in FIG. 1, the second terminal 242 in FIG. 2, the fourth terminal 328 in FIG. 3, or the fourth terminal 428 in FIG. 4). The second terminal of the dynamic biasing circuitry is coupled to the first terminal of the fifth transistor. In some examples, the dynamic biasing circuitry includes an LPF (e.g., the resistor R3 and the capacitor C1), a source follower (e.g., the transistor M11 in FIGS. 3 and 6), and a current mirror (e.g., the transistors M7 and M8 in FIGS. 3, 4, and 6).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. An integrated circuit (IC) comprising:
a first transistor having a first terminal, a second terminal, and a control terminal;
a second transistor having a first terminal, a second terminal, and a control terminal; and
cascode circuitry having a first terminal, a second terminal, a third terminal, a fourth terminal, a fifth terminal, and a sixth terminal, the first terminal of the cascode circuitry coupled to the control terminal of the first transistor, the second terminal of the cascode circuitry coupled to the control terminal of the second transistor, the third terminal of the cascode circuitry coupled to the second terminal of the first transistor, and the fourth terminal of the cascode circuitry coupled to the second terminal of the second transistor; and
dynamic biasing circuitry having a first terminal and a second terminal, the first terminal of the dynamic biasing circuitry coupled to the first terminals of the first and second transistors.

2. The IC of claim 1, further comprising:
switch voltage circuitry;
a third transistor having a first terminal, a second terminal, and a control terminal, the second terminal of the third transistor coupled to the first terminal of the cascode circuitry, and the control terminal of the third transistor coupled to the switch voltage circuitry; and
a fourth transistor having a first terminal, a second terminal, and a control terminal, the second terminal of the fourth transistor coupled to the second terminal of the cascode circuitry, and the control terminal of the fourth transistor coupled to the switch voltage circuitry.

3. The IC of claim 2, further comprising a fifth transistor having a first terminal, a second terminal, and a control terminal, the first terminal of the fifth transistor coupled to the second terminal of the dynamic biasing circuit, and the second terminal of the fifth transistor coupled to the first terminals of the first and second transistors.

4. The IC of claim 2, wherein the dynamic biasing circuitry includes a low-pass filter (LPF) circuit coupled to the first terminal of the dynamic biasing circuitry.

5. The IC of claim 4, wherein the dynamic biasing circuitry includes a fifth transistor having a first terminal, a second terminal, and a control terminal, the control terminal of the fifth transistor coupled to the LPF circuit.

6. The IC of claim 5, wherein the dynamic biasing circuitry includes a sixth transistor and a current mirror, the sixth transistor having a first terminal, a second terminal, and a control terminal, the current mirror having a first terminal and a second terminal, the control terminal of the sixth transistor coupled to the first terminal of the fifth transistor, and the first terminal of the current mirror coupled to the first terminal of the sixth transistor.

7. The IC of claim 5, wherein the dynamic biasing circuitry includes a surge current suppressor having a first terminal and a second terminal, the second terminal of the surge current suppressor coupled to the first terminal of the fifth transistor.

8. The IC of claim 7, wherein each of the first and second transistors has a respective body terminal, and the dynamic biasing circuitry is configured to provide a bias voltage to the body terminals of the first and second transistors.

9. A circuit comprising:
a transconductance amplifier stage including:
a first transistor having a first terminal, a second terminal, and a control terminal;
a second transistor having a first terminal, a second terminal, and a control terminal; and
cascode circuitry having a first terminal, a second terminal, a third terminal, a fourth terminal, a fifth terminal, and a sixth terminal, the first terminal of the cascode circuitry coupled to the second terminal of the first transistor, and the second terminal of the cascode circuitry coupled to the second terminal of the second transistor; and
dynamic biasing circuitry coupled to the first terminals of first and second transistors, the dynamic biasing circuitry configured to:
detect a voltage transient at a target terminal of the transconductance amplifier stage;
adjust a bias current responsive to the voltage transient; and
provide the adjusted bias current to the first terminals of the first and second transistors.

10. The circuit of claim 9, further comprising a gain stage having a first terminal, a second terminal, a third terminal, and a fourth terminal, the first terminal of the gain stage coupled to the fifth terminal of the cascode circuitry, and the second terminal of the gain stage coupled to the sixth terminal of the cascode circuitry.

11. The circuit of claim 10, further comprising an intermediate stage and an output stage, wherein the transconductance amplifier stage, the gain stage, the intermediate stage, and the output stage are stages of an amplifier.

12. The circuit of claim 10, further comprising a differential cross-coupled stage, a differential to single-ended stage, and a level shift and drivers stage, wherein the transconductance amplifier stage, the gain stage, the differential cross-coupled stage, the differential to single-ended stage, and the level shift and drivers stage are stages of a comparator.

13. The circuit of claim 9, wherein the dynamic biasing circuitry is configured to:
detect a low-to-high voltage transient at the target terminal; and
adjust the bias current with a first adjustment responsive to the low-to-high voltage transient.

14. The circuit of claim 13, wherein the dynamic biasing circuitry is configured to:
detect a high-to-low voltage transient at a target terminal; and
adjust the bias current with a second adjustment responsive to the high-to-low voltage transient, the second adjustment different than the first adjustment.

15. The circuit of claim 9, further comprising:
a third transistor having a first terminal, a second terminal, and a control terminal, the second terminal of the third transistor coupled to the first terminal of the cascode circuitry;
a fourth transistor having a first terminal, a second terminal, and a control terminal, the second terminal of the fourth transistor coupled to the second terminal of the cascode circuitry;
a fifth transistor having a first terminal, a second terminal, and a control terminal, the first terminal of the fifth transistor coupled to the first terminal of the third transistor, the second terminal of the fifth transistor coupled to the second terminal of the third transistor, and the fifth transistor being a native transistor; and
a sixth transistor having a first terminal, a second terminal, and a control terminal, the first terminal of the sixth transistor coupled to the first terminal of the fourth transistor, the second terminal of the sixth transistor coupled to the second terminal of the fourth transistor, and the sixth transistor being a native transistor.

16. The circuit of claim 9, wherein the cascode circuitry includes transient response circuitry, the transient response circuitry including a clamping network and discharge circuitry.

17. A circuit comprising:
a transconductance amplifier stage including:
a first transistor having a first terminal, a second terminal, and a control terminal;
a second transistor having a first terminal, a second terminal, and a control terminal;
a third transistor having a first terminal, a second terminal, and a control terminal;
a fourth transistor having a first terminal, a second terminal, and a control terminal;
a fifth transistor having a first terminal, a second terminal, and a control terminal, the second terminal of the fifth transistor coupled to the first terminals of the first and second transistors; and
cascode circuitry having a first terminal, a second terminal, a third terminal, a fourth terminal, a fifth terminal, and a sixth terminal, the first terminal of the cascode circuitry coupled to the control terminal of the first transistor and the second terminal of the third transistor, and the second terminal of the cascode circuitry coupled to the control terminal of the second transistor and the second terminal of the fourth transistor, the third terminal of the cascode circuitry coupled to the second terminal of the first transistor, the fourth terminal of the cascode circuitry coupled to the second terminal of the second transistor; and
dynamic biasing circuitry having a first terminal and a second terminal, the second terminal of the dynamic biasing circuitry coupled to the first terminal of the fifth transistor.

18. The circuit of claim 17, wherein the dynamic biasing circuitry includes a low-pass filter (LPF), a source follower, and a current mirror.

19. The circuit of claim 17, wherein the dynamic biasing circuitry is configured to:
detect a low-to-high voltage transient at the first terminals of the first and second transistors;
adjust a bias current with a first adjustment responsive to the low-to-high voltage transient; and
provide the adjusted bias current at the second terminal of the dynamic biasing circuitry.

20. The circuit of claim 19, wherein the dynamic biasing circuitry is configured to:
detect a high-to-low voltage transient at the first terminals of the first and second transistors;
adjust the bias current with a second adjustment responsive to the high-to-low voltage transient, the second adjustment different than the first adjustment; and
provide the adjusted bias current at the second terminal of the dynamic biasing circuitry.
